(19) United States
(12) Patent Application Publication
(10) Pub. No.: US 2026/0040548 A1
(43) Pub. Date: Feb. 5, 2026

(54) MULTI-DIMENSION METAL-INSULATOR-METAL CAPACITOR

(71) Applicant: Micron Technology, Inc., Boise, ID (US)

(72) Inventors: Nicolo GRAVELLINI, Milan (IT); Lorenzo PEDRAZZETTI, Cremona (IT); Giovanni MAZZONE, Villasanta (IT); Paolo TESSARIOL, Arcore (IT); Michele PICCARDI, Cupertino, CA (US)

(21) Appl. No.: 19/222,197

(22) Filed: May 29, 2025

Related U.S. Application Data
(60) Provisional application No. 63/677,803, filed on Jul. 31, 2024.

(51) Int. Cl. H10B 43/27; H01L 23/522; H10B 41/27; H10B 41/35; H10B 43/35; H10D 1/68

(52) U.S. Cl. CPC H10B 43/27; H01L 23/5223; H10B 41/27; H10B 41/35; H10B 43/35; H10D 1/68

(57) ABSTRACT

Embodiments described herein relate to various structures, integrated assemblies, and memory devices. In some embodiments, an integrated assembly includes a device region. The device region includes a capacitor structure that includes a first conductive spiral structure that is horizontally disposed and a second conductive spiral structure that is horizontally disposed. In some embodiments, the second conductive spiral structure interleaves with the first conductive spiral structure.

### CROSS-REFERENCE TO RELATED APPLICATION

This Patent Application claims priority to U.S. Provisional Patent Application No. 63/677,803, filed on Jul. 31, 2024, entitled “MULTI-DIMENSION METAL-INSULATOR-METAL CAPACITOR,” and assigned to the assignee hereof. The disclosure of the prior Application is considered part of and is incorporated by reference into this Patent Application.

### TECHNICAL FIELD

The field of semiconductor device fabrication encompasses the creation and refinement of various components for electronic circuits. This domain includes the development of capacitor structures to meet the requirements of integrated circuit functionality.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### SUMMARY OF THE INVENTION

An aspect of the present disclosure is directed to an integrated assembly, comprising: a device region, comprising: a capacitor structure, comprising: a first conductive pectinate structure that is horizontally disposed and interleaves with a second conductive pectinate structure that is horizontally disposed, wherein first beams of the first conductive pectinate structure and second beams of the second conductive pectinate structure are spaced on the same nominal pitch, and wherein the first beams and the second beams have the same nominal length: and a third conductive pectinate structure that is horizontally disposed interleaving with a fourth conductive pectinate structure that is horizontally disposed, wherein third beams of the third conductive pectinate structure and fourth beams of the fourth conductive pectinate structure are spaced on the same nominal pitch as the first beams and the second beams, wherein the third beams and the fourth beams have the same nominal length as the first beams and the second beams, wherein the third beams are vertically aligned with the first beams, and wherein the fourth beams are vertically aligned with the second beams.

Another aspect of the present disclosure is directed to an integrated assembly, comprising: a device region, comprising: a capacitor structure, comprising: a first conductive spiral structure that is horizontally disposed: and a second conductive spiral structure that is horizontally disposed, wherein the second conductive spiral structure interleaves with the first conductive spiral structure.

Another aspect of the present disclosure is directed to an integrated assembly, comprising: a device region, comprising: a capacitor structure, comprising: a first conductive pectinate structure comprising: a first set of sinusoidal beams that are horizontally disposed within a metallization layer of the device region: and a second conductive pectinate structure, comprising: a second set of sinusoidal beams that are horizontally disposed within the metallization layer and interleave with the first set of sinusoidal beams.

Another aspect of the present disclosure is directed to a method, comprising: forming a first dielectric layer: forming a first cavity complex that includes a first set of interleaving pectinate patterns in the first dielectric layer: forming a first set of interleaving conductive pectinate structures in the interleaving pectinate patterns: forming a second dielectric layer over the first dielectric layer and the first set of interleaving conductive pectinate structures: forming a third dielectric layer over the second dielectric layer: forming a fourth dielectric layer over the third dielectric layer: forming a second cavity complex that includes a second set of interleaving pectinate patterns in the fourth dielectric layer and a pattern of vias that extend from the second set of interleaving pectinate patterns to beams of the first set of interleaving conductive pectinate structures: and forming a set of interconnect structures in the vias and a second set of interleaving conductive pectinate structures in the second set of interleaving pectinate patterns, wherein the set of interconnect structures electrically couples the second set of interleaving conductive pectinate structures with the first set of interleaving conductive pectinate structures to form at least a portion of a three-dimensional capacitor structure.

Yet another aspect of the present disclosure is directed to a method, comprising: forming a dielectric layer: forming a cavity complex that includes a set of interleaving spiral patterns in the dielectric layer: and forming a set of interleaving conductive spiral structures in the cavity complex.

### BRIEF DESCRIPTION OF THE DRAWINGS

FIG. 1 is a circuit diagram of an example memory cell described herein.

FIG. 2 is an example diagrammatic view of an example charge pump circuit described herein.

FIG. 3 shows a diagrammatic side view of a semiconductor device described herein.

FIG. 4A and FIG. 4B include diagrammatic views of an example implementation described herein.

FIG. 5A and FIG. 5B include diagrammatic views of an example implementation described herein.

FIG. 6 includes a diagrammatic view of an example implementation described herein.

FIG. 7 is a flowchart of an example method of forming an integrated assembly or memory device having a multi-dimension capacitor structure described herein.

FIG. 8 is a flowchart of an example method of forming an integrated assembly or memory device having a multi-dimension capacitor structure described herein.

FIGS. 9A through 9J are diagrammatic views showing formation of the capacitor structure at example process stages of an example process of forming the capacitor structure.

FIG. 10 is a diagram of example components included in a memory array described herein.

### DETAILED DESCRIPTION

A NAND semiconductor device is a cornerstone of modern memory technology, commonly utilized in USB drives, SSDs (Solid State Drives), and memory cards. Central to its operation is the NAND gate, a logic gate that facilitates logical conjunctions on input signals. These gates are arranged into a grid-like structure within the device, forming memory cells capable of storing binary digits, or “bits,” denoted by the presence or absence of an electrical charge or a threshold amount of electrical charge.

The relationship between NAND memory cells and a charge pump, integrated with capacitors, significantly influences the device's functionality and performance. Charge pumps generate the higher voltage levels required for various operations, including programming and erasing memory cells.

The efficiency and performance of charge pumps are important. These charge pumps rely on capacitors to store and release electrical charge, a process central to the generation of higher voltage levels necessary for programming and erasing memory cells. The capacitance of these capacitors influence the efficiency of charge pumps. High-capacitance capacitors contribute to more effective energy storage and transfer, resulting in enhanced device functionality and performance. In some cases, a comb-like capacitor structure may be used across multiple levels of metal layers, where the comb-like capacitor structure includes arrangements of beam structures having different pitches, sizes, or staggered positions that introduce limitations in terms of optimizing capacitance and pump efficiency.

With the advancement in integrated circuit (IC) technology and the transition to advanced nodes (e.g., smaller geometries), the size of copper area pockets used to enhance performance or reliability of capacitors included in charges pumps decreases. intensifying the need for improved charge pump efficiency to prevent the capacitors from becoming a performance bottleneck. Metal-Insulator-Metal (MIM) capacitor architectures (e.g., the comb-like capacitor structure including arrangements of beam structures having different pitches, sizes, or staggered arrangements) have the challenge of providing adequate capacitance per unit area without compromising device performance, energy efficiency, or array efficiency. Some configurations, while functional, are becoming less suitable for addressing the increasing demands for higher performance and energy efficiency in smaller geometries. The technical problem, therefore, lies in the need for innovative capacitor architectures that can enhance capacitance per unit area and charge pump efficiency without increasing the footprint or compromising the performance of NAND semiconductor devices.

Some embodiments described herein provide a method for improving capacitor architecture in semiconductor devices to enhance capacitance per unit area and charge pump efficiency. For example, the method includes forming a capacitor structure with conductive pectinate structures that are horizontally disposed and interleaved with each other, where the beams of these structures are spaced on the same pitch and have the same length. In some aspects, the method also involves vertically aligning and electrically coupling these beams through interconnect structures to form a three-dimensional capacitor structure. This three-dimensional structure can be implemented with various configurations, such as vertically arranged, interleaving comb structures (e.g., interleaving pectinate structures) having substantial overlap, vertical contacts connecting legs across metal levels, and even interleaving sinusoidal structures or interleaving spiral structures.

In this way, the invention addresses the need for improved capacitor architectures by leveraging both 2D layout optimization and 3D structural enhancements. This results in increased capacitance per unit area, reduced parasitic capacitance, and improved charge pump efficiency, thereby improving performance of NAND semiconductor devices as they advance to smaller geometries.

By adopting the new MIM capacitor architectures, semiconductor devices can achieve technical advancements in their operational efficiency. For example, the reduction in parasitic capacitance may directly correlate to an enhancement in charge pump efficiency by reducing delays in signal propagation or reducing power losses. Such an enhancement may lead to a lower energy per bit (EpB) for the operation of the device, which is a factor for the conservation of processing resources and energy in high-density NAND semiconductor devices. Additionally, the increase in MIM capacitance per unit area can lead to improved array efficiency or maintain the same area while achieving a higher capacitance, which can contribute to faster programming and read operations. Furthermore, the technical improvement of the shape of vertical contacts can improve capacitive coupling, which improves the electrical performance of the device. The proposed architectures offer a solution to the technical challenges posed by comb-like capacitor structures, facilitating the progression of NAND devices towards meeting the needs for higher performance and energy efficiency in reduced geometries.

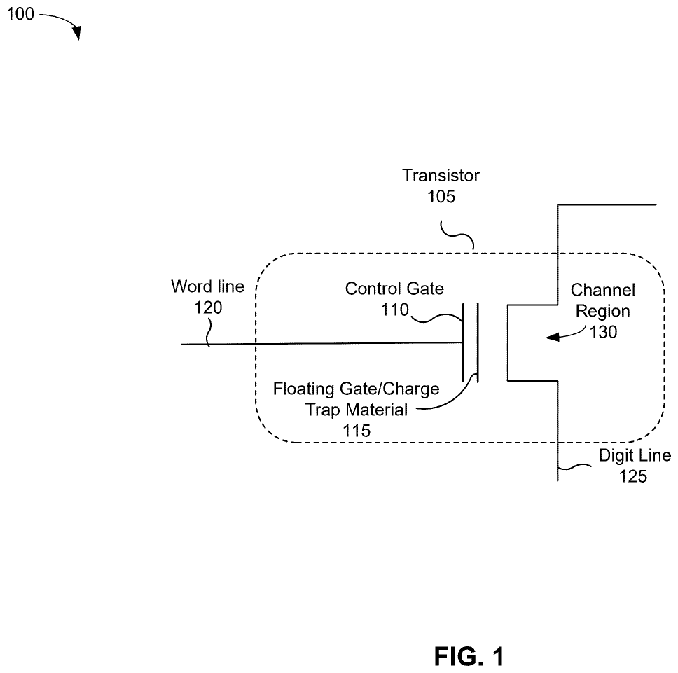

FIG. 1 is a circuit diagram of an example memory cell 100 described herein. In some embodiments, the memory cell 100 is a NAND memory cell. As shown in FIG. 1, the memory cell 100 may include a transistor 105 that includes a control gate 110, a floating gate/charge trap material 115, and a channel region 130.

The transistor 105 may store bits of data by trapping electrons on the floating gate/charge trap material 115. For example, a presence of electrons (e.g., trapped electrons) on the floating gate/charge trap material 115 may correspond to a logic state “0,” while an absence of electrons from the floating gate/charge trap material 115 may correspond to a logic state “1.” In some embodiments, the floating gate/charge trap material 115 may be a floating gate. In some embodiments, the floating gate/charge trap material may be a charge trap material. Use of the transistor 105 allows for non-volatile data storage, meaning that the data persists even if power is removed from the memory cell 100. As such, a capacitor that may be used in other types of memory cells is not needed.

The transistor 105 (e.g., the memory cell 100) may be accessed (e.g., written to, read from, or erased) using signals on a combination of lines that are coupled to transistor 105, shown as a word line 120 (sometimes called an “access line”) that is connected to the control gate 110 and a digit line 125 (sometimes called a “bit line”) that is connected to a channel region 130.

Writing data to or reading data from the transistor 105 may involve applying different sets of voltages to the control gate 110 (via the word line 120) and the digit line 125. A first set of voltages may create a first electric field in the channel region 130 that facilitates movement and trapping of electrons onto the floating gate/charge trap material 115, establishing the logic state “0.” A second set of voltages may create a second electric field in the channel region 130 that facilitates movement and removal of electrons from the floating gate/charge trap material 115, establishing the logic state “1.” A third set of specific voltages may create a third electric field in the channel region 130 that facilitates a measurement of a threshold voltage of the transistor 105 that corresponds to a logic state.

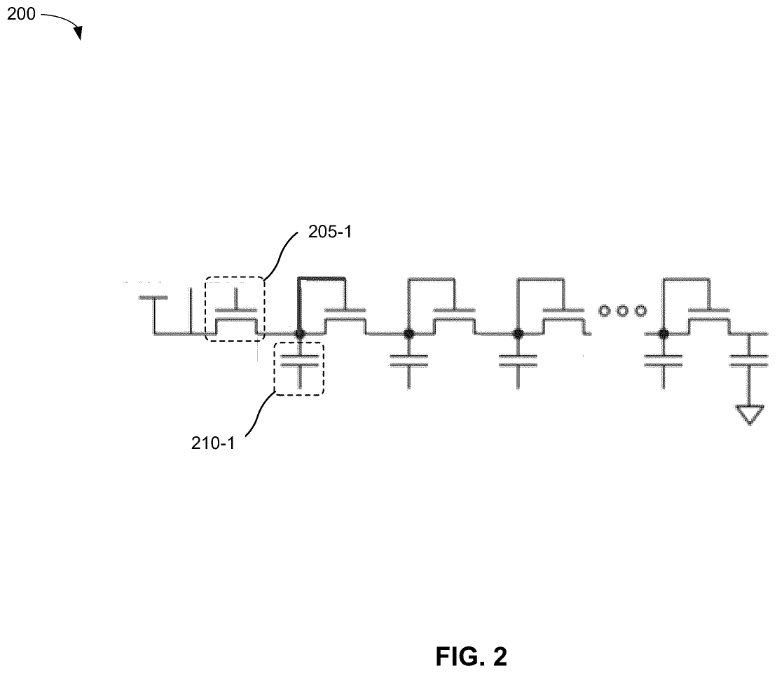

As described in greater detail in connection with FIGS. 2-10, and in some embodiments, a charge pump circuit is used to generate a voltage level for various operations, including programming and erasing of the memory cell 100. The charge pump circuit may include capacitor structures of different configurations or features, such as vertically arranged, interleaving comb structures (conductive pectinate structures) having substantial overlap, vertical contacts connecting legs across metal levels, and even sinusoidal structures or square-shaped spiral structures.

As indicated above, FIG. 1 is provided as an example. Other examples may differ from what is described with respect to FIG. 1.

FIG. 2 is an example diagrammatic view of an example charge pump circuit 200 described herein. In some embodiments, the charge pump circuit 200 is electrically coupled with the memory cell 100 of FIG. 1.

The charge pump circuit 200 (e.g., a voltage multiplier circuit), leverages a series of transistor structures 205 and capacitor structures 210 to amplify voltages. The charge pump circuit 200 operates through a cyclical process of charging and discharging the capacitor structures 210, enabling the generation of an output voltage higher than the input.

During the charging phase, the transistor structure 205 connected to an input voltage source permits current flow, charging the capacitor structure 210 to the input voltage level. In the subsequent discharging phase, the capacitor structure 210 (e.g., a charged capacitor structure) is isolated from the input source as the transistor structure 205 switches off. Another transistor structure 205, linked to a higher voltage level, facilitates the discharge of the capacitor structure 210 into the next stage, effectively doubling the voltage across it.

The cycle repeats for each stage of transistor structures 205 and capacitor structures 210, with each stage multiplying the voltage from the preceding one. Through cascading multiple stages, the charge pump circuit 200 achieves significantly elevated output voltages compared to the input. By orchestrating the timing and switching of the transistor structures 205, the charge pump circuit 200 ensures efficient voltage multiplication, rendering it applicable across various scenarios requiring higher voltages with relatively lower inputs.

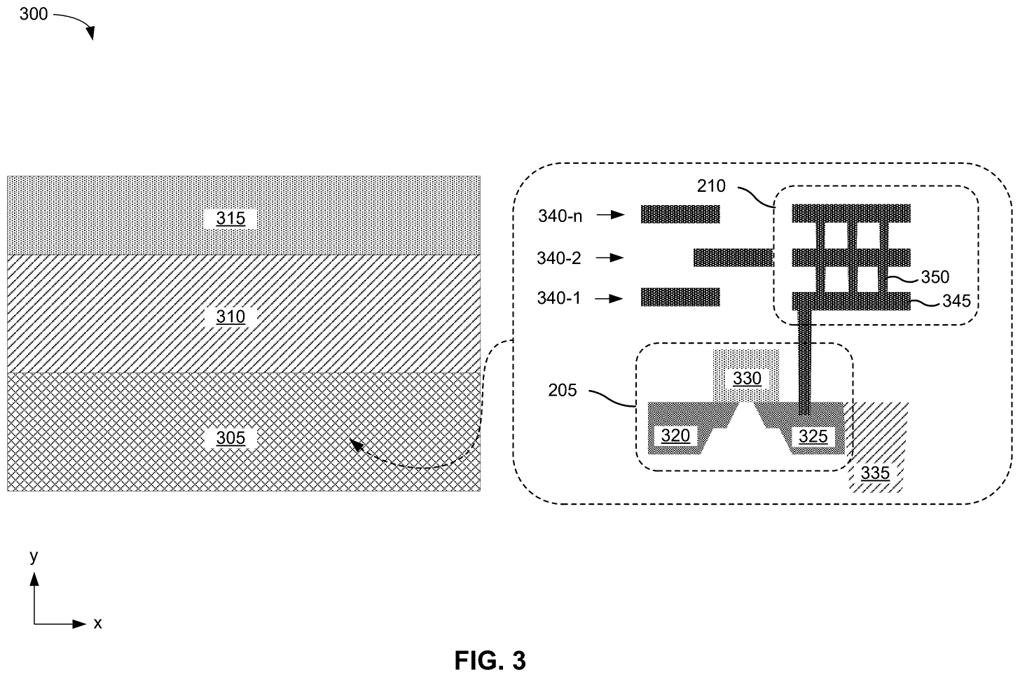

As described in greater detail in connection with FIGS. 3 through FIG. 10, the capacitor structure 210 may include different configurations or features, such as vertically arranged, interleaving comb-like structures (e.g., interleaving pectinate structures) having substantial overlap, vertical contacts connecting legs across metal levels, and even interleaving sinusoidal or interleaving spiral structures.

FIG. 3 shows a diagrammatic side view of a semiconductor device 300 described herein. As shown in FIG. 3, the semiconductor device 300, which may be a NAND semiconductor device, may include a device region 305, a cell stack region 310, and an interconnect region 315. The device region 305 may include integrated circuitry including one or more portions of the charge pump circuit 200 of FIG. 2. The cell stack region 310 may include integrated circuitry including one or more portions of the memory cell 100 of FIG. 1. The interconnect region 315 (sometimes referred to as a backend of line (BEOL) region) may include traces or interconnects for electrically coupling integrated circuitry of the device region 305 or the cell stack region 310 with another device external to the semiconductor device 300.

As shown in the detailed view, the device region 305 includes the transistor structure 205, which includes a source region 320, a drain region 325, and gate structure 330. The source region 320 or the drain region 325 may be a semiconductor and may comprise, consist of, or consist essentially of semiconductive material. The semiconductive material may comprise, consist of, or consist essentially of silicon (e.g., polycrystalline silicon), among other examples. In some embodiments, the source region 320 may be a same material as or a different material than the drain region 325. In some embodiments, the source region 320 or the drain region 325 include a dopant that changes electrical conductivity properties of the source region 320 or the drain region 325.

The gate structure 330 may be an electrical conductor and may comprise, consist of, or consist essentially of conductive material. The conductive material may comprise, consist of, or consist essentially of a metal (e.g., titanium, tungsten, cobalt, nickel, platinum, or ruthenium), a metal composition (e.g., a metal silicide, a metal carbide, or a metal nitride, such as titanium nitride or titanium silicon nitride), or a conductively-doped semiconductor material (e.g., conductively-doped silicon, conductively-doped germanium, or conductively-doped gallium arsenide), among other examples.

In some embodiments, a shallow trench isolation (STI) region 335 is proximate to the transistor structure 205. The STI region 335, which may electrically isolate the transistor structure 205 from other structures or integrated circuitry within the device region 305, may be an electrical insulator and may comprise, consist of, or consist essentially of insulative material. The insulative material may comprise, consist of, or consist essentially of silicon dioxide or silicon nitride, among other examples.

As shown in FIG. 3, the device region 305 further includes the capacitor structure 210, where the capacitor structure 210 electrically couples with the transistor structure 205. The capacitor structure 210 may be in one or more metallization layers 340 of the device region 305.

The metallization layers 340 may be an electrical conductor and may comprise, consist of, or consist essentially of conductive material. The conductive material may comprise, consist of, or consist essentially of a metal (e.g., titanium, tungsten, cobalt, nickel, platinum, or ruthenium), a metal composition (e.g., a metal silicide, a metal carbide, or a metal nitride, such as titanium nitride or titanium silicon nitride), or a conductively-doped semiconductor material (e.g., conductively-doped silicon, conductively-doped germanium, or conductively-doped gallium arsenide), among other examples. Further, the metallization layers 340 may be separated by respective dielectric layers (excluded from FIG. 3 for clarity).

As further shown in the detailed view, the capacitor structure 210 may include one or more conductive structures 345 that are vertically oriented and that electrically couple with interconnect structures 350. The conductive structures 345 or the interconnect structures 350 are electrical conductors and may comprise, consist of, or consist essentially of conductive material. The conductive material may comprise, consist of, or consist essentially of a metal (e.g., titanium, tungsten, cobalt, nickel, platinum, or ruthenium), a metal composition (e.g., a metal silicide, a metal carbide, or a metal nitride, such as titanium nitride or titanium silicon nitride), or a conductively-doped semiconductor material (e.g., conductively-doped silicon, conductively-doped germanium, or conductively-doped gallium arsenide), among other examples.

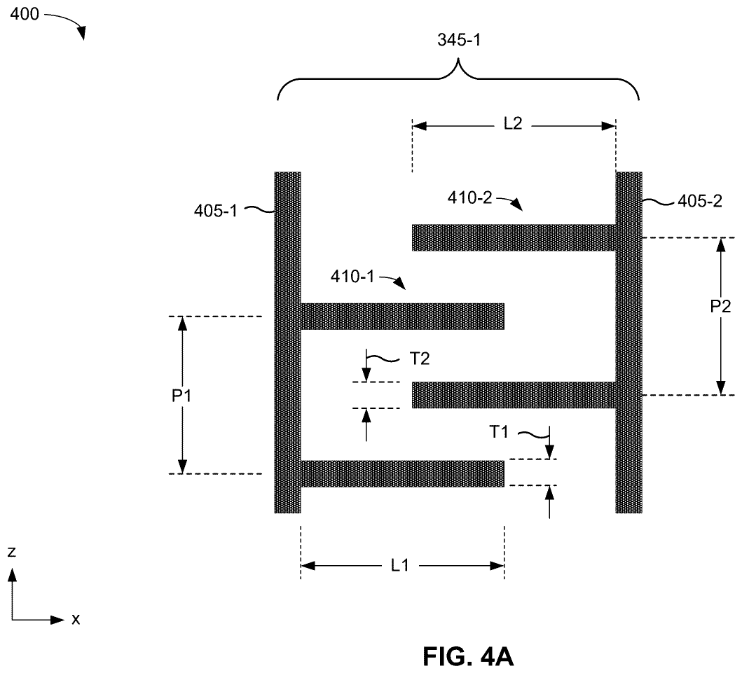

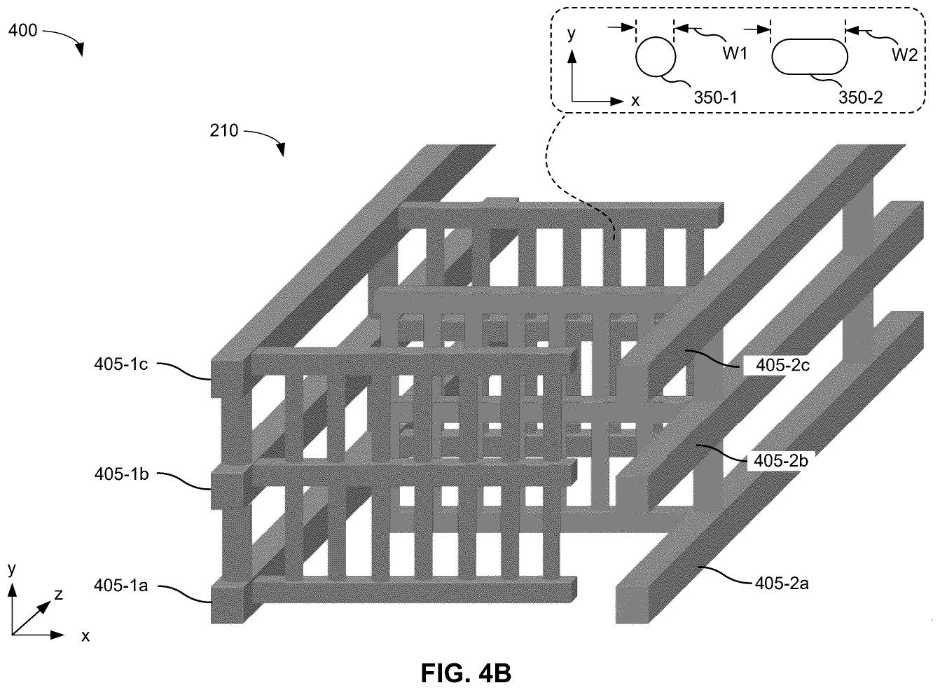

As described in greater detail in connection with FIG. 4A through FIG. 9J, the conductive structures 345 may include interleaving conductive pectinate structures (e.g., comb-like structures) or interleaving spiral structures. Additionally, or alternatively, the conductive structures 345 may include portions or segments formed from approximately linear or sinusoidal beams. Additionally, or alternatively, the interconnect structures 350 may have different dimensions or cross-sectional shapes to optimize capacitive coupling among the conductive structures 345.

As indicated above, FIG. 3 is provided as an example. Other examples may differ from what is described with regard to FIG. 3.

FIG. 4A and FIG. 4B include diagrammatic views of an example implementation 400 described herein. The conductive structure 345-1 of implementation 400 (e.g., a conductive structure of the capacitor structure 210) includes interleaving conductive pectinate structures 405 (e.g., comb-like structures) that are horizontally disposed in a metallization layer (e.g., the metallization layer 340).

As shown in the top view of FIG. 4A, the conductive structure 345-1 includes the conductive pectinate structure 405-1 that interleaves with the conductive pectinate structure 405-2. In some embodiments, and as shown in FIG. 4A, the conductive pectinate structure 405-1 includes one or more approximately linear beams 410-1, and the conductive pectinate structure 405-2 includes one or more approximately linear beams 410-2. Within a capacitor structure (e.g., the capacitor structure 210), the conductive pectinate structure 405-1 may be of a first electrical polarity, and the conductive pectinate structure 405-2 may be of a second, opposite electrical polarity.

The conductive pectinate structures 405-1 and 405-2 may have substantially similar or same nominal geometric properties or dimensions. In other words, differences in geometric properties or dimensions may be limited to differences that are induced through variations or differences in a repeatability of one or more semiconductor manufacturing tools used to fabricate the conductive pectinate structures 405-1 and 405-2.

For example, the beams 410-1 may be spaced on a nominal pitch P1, and the beams 410-2 may be spaced on a nominal pitch P2, where the nominal pitch PI and the nominal pitch P2 are the same. Additionally, or alternatively, the beams 410-1 may have a nominal thickness T1, and the beams 410-2 may have a nominal thickness T2, where the nominal thickness T1 and the nominal thickness T2 are the same. Additionally, or alternatively, the beams 410-1 may have a nominal length L1, and the beams 410-2 may have a nominal length L2, where the nominal length L1 and the nominal length L2 are the same.

As shown in the isometric view of FIG. 4B, the capacitor structure 210 may include multiple, vertically arranged conductive pectinate structures 405. For example, and as part of a first metallization layer (e.g., the metallization layer 340-1 of FIG. 3), the capacitor structure 210 may include the conductive pectinate structure 405-1a that interleaves with the conductive pectinate structure 405-1b. Additionally, or alternatively and as part of a second metallization layer (e.g., the metallization layer 340-2 of FIG. 3), the capacitor structure 210 may include the conductive pectinate structure 405-1b that interleaves with the conductive pectinate structure 405-2b. Additionally, or alternatively and as part of a third metallization layer (e.g., the metallization layer 340-3 of FIG. 3), the capacitor structure 210 may include the conductive pectinate structure 405-1c that interleaves with the conductive pectinate structure 405-2c.

The conductive pectinate structure 405-1b may vertically align with (e.g., may be directly above or at least partially overlap with) the conductive pectinate structure 405-1a, and the conductive pectinate structure 405-2b may vertically align with (e.g., be directly above or at least partially overlap with) the conductive pectinate structure 405-2a. Additionally, or alternatively, the conductive pectinate structure 405-1c may vertically align with (e.g., be directly above or at least partially overlap with) the conductive pectinate structure 405-1b, and the conductive pectinate structure 405-2c may vertically align with (e.g., directly above or at least partially overlap with) the conductive pectinate structure 405-2b. Furthermore, the conductive pectinate structures 405-1a, 405-2a, 405-1b, 405-2b, 405-1c and 405-2c may share substantially similar geometric shapes and dimensions.

Although FIG. 4B shows the capacitor structure 210 including three sets of interleaving conductive pectinate structures 405 (e.g., the conductive pectinate structures 405-1a through 405-1c that interleave with the conductive pectinate structures 405-2a through 405-2c), in some embodiments the capacitor structure 210 includes fewer than three sets of interleaving conductive pectinate structures 405 (e.g. two sets). Alternatively, and in some embodiments, the capacitor structure 210 includes more than three sets of interleaving conductive pectinate structures 405 (e.g., four sets, five sets, and so on).

In some embodiments, at least one interconnect structure 350 (or an array of interconnect structures 350) may electrically couple (e.g., capacitively couple) a pair of the conductive pectinate structures 405 that are vertically aligned or at least partially overlapped. Furthermore, and in some embodiments, incorporation of the interconnect structure 350 (or an array of interconnect structures 350) increases a total capacitance of the capacitor structure 210.

The interconnect structure 350 may have a width selected to “tune” a performance (e.g., an equivalent series resistance, a frequency response, or a voltage rating) of a capacitor structure (e.g., the capacitor structure 210) including the conductive pectinate structures. For example, and as shown in FIG. 4B, the interconnect structure 350-1 may have a width W1 that is less than or equal to a thickness of beams (e.g., the thickness T1 or T2) of the conductive pectinate structures 405. Alternatively, and as shown in FIG. 4B, the interconnect structure 350-2 may be elongated and have a width W2 that is greater than the thickness of the beams of the conductive pectinate structures 405.

As indicated above, FIGS. 4A and 4B are provided as an example. Other examples may differ from what is described with regard to FIGS. 4A and 4B.

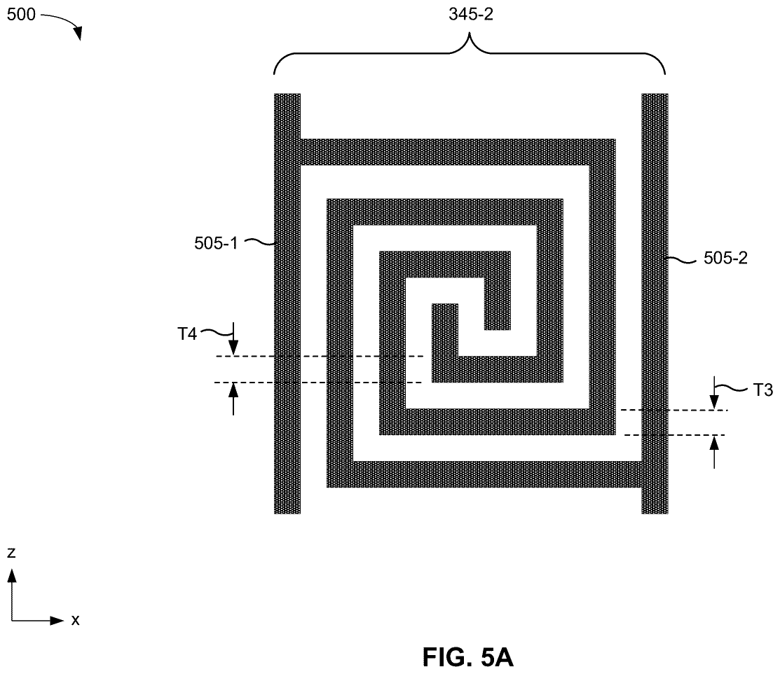

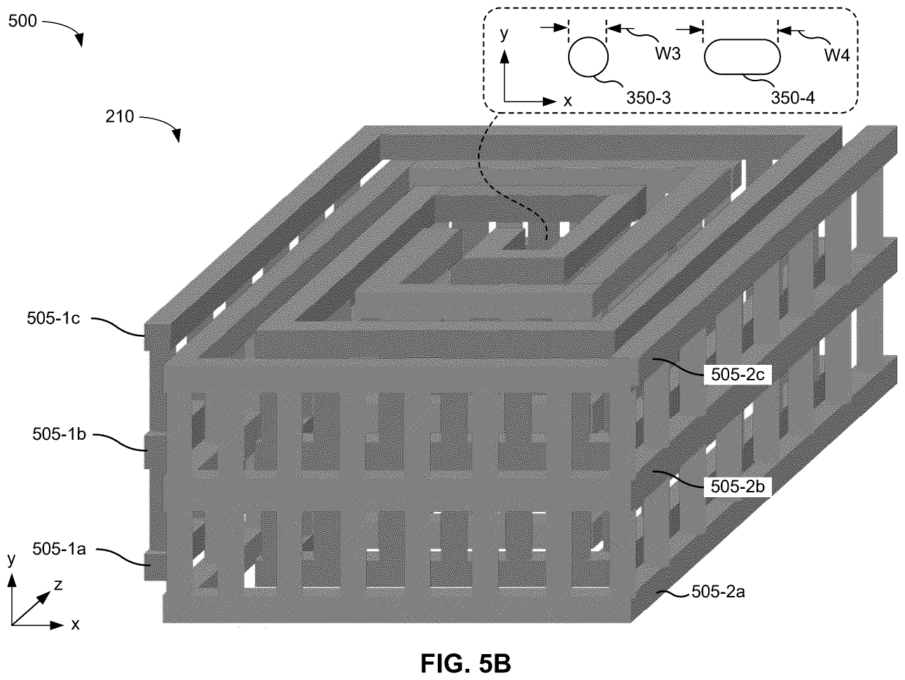

FIGS. 5A and FIG. 5B include diagrammatic views of an example implementation 500 described herein. The conductive structure 345-2 of implementation 500 (e.g., conductive structures of the capacitor structure 210) include interleaving conductive spiral structures 505 that are horizontally disposed within a metallization layer (e.g., the metallization layers 340).

As shown in the top view of FIG. 5A, the conductive structure 345-2 includes the conductive spiral structure 505-1 that interleaves with the conductive spiral structure 505-2. Within a capacitor structure (e.g., the capacitor structure 210), the conductive spiral structure 505-1 may be of a first electrical polarity and the conductive spiral structure 505-2 may be of a second, opposite electrical polarity. Further, and although the conductive spiral structures 505-1 and 505-2 are shown as square-shaped conductive spiral structures in FIG. 5A, other shapes (curved, rectangular, or triangular shapes, among other examples) are within the scope of the present disclosure.

The conductive spiral structures 505-1 and 505-2 may have substantially similar or same nominal geometric properties or dimensions. In other words, differences in geometric properties or dimensions may be limited to differences that are induced through variations or differences in a repeatability of one or more semiconductor manufacturing tools used to fabricate the conductive spiral structures 505-1 and 505-2. For example, segments of the conductive spiral structure 505-1 may have a nominal thickness T3, and segments of the conductive spiral structure 505-2 may have a nominal thickness T4, where the nominal thickness T3 and the nominal thickness T4 are the same.

As shown in the isometric view of FIG. 5B, the capacitor structure 210 may include multiple, vertically arranged conductive spiral structures 505. For example, and as part of a first metallization layer (e.g., the metallization layer 340-1 of FIG. 3), the capacitor structure 210 may include a conductive spiral structure 505-1a that interleaves with the conductive spiral structure 505-2a. Additionally, or alternatively and as part of a second metallization layer (e.g., the metallization layer 340-2 of FIG. 3), the capacitor structure 210 may include the conductive spiral structure 505-1b that interleaves with the conductive spiral structure 505-2b. Additionally, or alternatively and as part of a third metallization layer (e.g., the metallization layer 340-3 of FIG. 3), the capacitor structure 210 may include the conductive spiral structure 505-1c that interleaves with the conductive spiral structure 505-2c.

The conductive spiral structure 505-1b may vertically align with (e.g., be directly above or at least partially overlap with) the conductive spiral structure 505-1a, and the conductive spiral structure 505-2b may vertically align with (e.g., be directly above or overlap with) the conductive spiral structure 505-2a. Additionally, or alternatively, the conductive spiral structure 505-1c may vertically align with (e.g., be directly above or overlap with) the conductive spiral structure 505-1b, and the conductive spiral structure 505-2c may vertically align with (e.g., be directly above or at least partially overlap with) the conductive spiral structure 505-2b. Furthermore, the conductive spiral structures 505-1a, 505-2a, 505-1b, 505-2b, 505-1c and 505-2c may share substantially similar geometric shapes and dimensions.

Although FIG. 5B shows the capacitor structure 210 including three sets of interleaving conductive spiral structures 505 (e.g., the conductive spiral structures 505-1a through 505-1c that interleave with the conductive spiral structures 505-2a through 505-2c), in some embodiments the capacitor structure 210 includes fewer than three sets of interleaving conductive spiral structures 505 (e.g. two sets). Alternatively, and in some embodiments, the capacitor structure 210 includes more than three sets of interleaving conductive spiral structures 505 (e.g., four sets, five sets, and so on).

In some embodiments, at least one interconnect structure 350 (or an array of interconnect structures 350) may electrically couple (e.g., capacitively couple) a pair of the conductive spiral structures 505 that are vertically aligned (e.g., at least partially overlap/underlap one another). Furthermore, and in some embodiments, incorporation of the interconnect structure 350 (or an array of interconnect structures 350) increases a total capacitance of the capacitor structure 210.

The interconnect structure 350 may have a width selected to “tune” a performance (e.g., an equivalent series resistance, a frequency response, or a voltage rating) of a capacitor structure (e.g., the capacitor structure 210) including the conductive spiral structures. For example, and as shown in FIG. 5B, the interconnect structure 350-3 may have a width W3 that is less than or equal to a thickness of segments (e.g., the thickness T3 or T4) of the conductive spiral structures 505. Alternatively, and as shown in FIG. 5B, the interconnect structure 350-4 may be elongated and have a width W4 that is greater than the thickness of the segments of the conductive spiral structures 505.

As indicated above, FIGS. 5A and 5B are provided as an example. Other examples may differ from what is described with regard to FIGS. 5A and 5B.

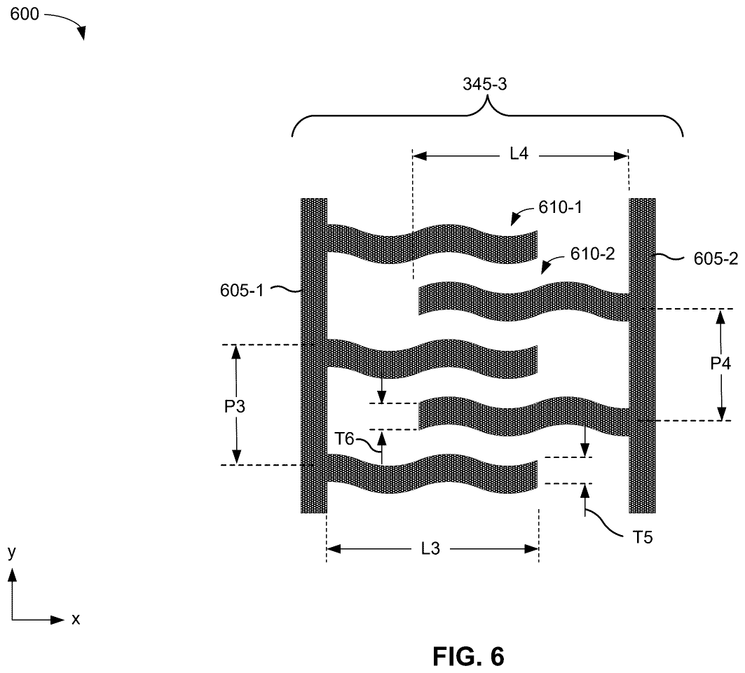

FIG. 6 includes a diagrammatic view of an example implementation 600 described herein. The conductive structure 345-3 of implementation 600 (e.g., a conductive structure of the capacitor structure 210) includes interleaving conductive pectinate structures 605 (e.g., comb-like structures) that are horizontally disposed.

As shown in the top view of FIG. 6, the conductive structure 345-3 includes the conductive pectinate structure 605-1 that interleaves with the conductive pectinate structure 605-2. In some embodiments, and in contrast to implementation 400 described in connection with FIGS. 4A and 4B, the conductive pectinate structure 605-1 includes one or more approximately sinusoidal beams 610-1, and the conductive pectinate structure 605-2 includes one or more sinusoidal beams 610-2. Within a capacitor structure (e.g., the capacitor structure 210), the conductive pectinate structure 605-1 may be of a first electrical polarity and the conductive pectinate structure 605-2 may be of a second, opposite electrical polarity.

The conductive pectinate structures 605-1 and 605-2 may have substantially similar or same nominal geometric properties or dimensions. In other words, differences in geometric properties or dimensions may be limited to differences that are induced through variations or differences in a repeatability of one or more semiconductor manufacturing tools used to fabricate the conductive pectinate structures 605-1 and 605-2.

For example, a spacing of the beams 610-1 may be on a nominal pitch P3, and a spacing of the beams 610-2 may on a nominal pitch P4, where the nominal pitch P3 and the nominal pitch P4 are the same. Additionally, or alternatively, the beams 610-1 may have a nominal thickness T5, and the beams 610-2 may have a nominal thickness T6, where the nominal thickness T5 and the nominal thickness T6 are the same. Additionally, or alternatively, the beams 610-1 may have a nominal length L3, and the beams 610-2 may have a nominal length L4, where the nominal length L3 and the nominal length L4 are the same.

As indicated above, FIG. 6 is provided as an example. Other examples may differ from what is described with regard to FIG. 6.

As described in connection with FIG. 1 through FIG. 6, and in some embodiments, an integrated assembly (e.g., the semiconductor device 300) includes a device region (e.g., the device region 305). The device region includes a capacitor structure (e.g., the capacitor structure 210) that includes a first conductive pectinate structure (e.g., the conductive pectinate structure 405-1a) that is horizontally disposed and interleaves with a second conductive pectinate structure (e.g., the conductive pectinate structure 405-2a) that is horizontally disposed. First beams (e.g., the beams 410-1) of the first conductive pectinate structure and second beams (e.g., the beams 410-2) of the second conductive pectinate structure may be spaced on a same nominal pitch (e.g., the pitch P1, P2). The first beams and the second beams may have a same nominal length (e.g., the length L1, L2). The capacitor structure includes a third conductive pectinate structure (e.g., the conductive pectinate structure 405-1b) that is horizontally disposed interleaving with a fourth conductive pectinate structure (e.g., the conductive pectinate structure 405-2b) that is horizontally disposed. Third beams of the third conductive pectinate structure (e.g., the beams 410-1) and fourth beams of the fourth conductive pectinate structure (e.g., the beams 410-2) are spaced on the same nominal pitch (e.g., the pitch P1, P2) as the first beams and the second beams. The third beams and the fourth beams may have the same nominal length (e.g., the length L1, L2) as the first beams and the second beams. In some embodiments, the third beams are vertically aligned with the first beams. In some embodiments, the fourth beams are vertically aligned with the second beams.

Additionally, or alternatively and in some embodiments, an integrated assembly (e.g., the semiconductor device 300) includes a device region (e.g., the device region 305). The device region includes a capacitor structure (e.g., the capacitor structure 210) that includes a first conductive spiral structure (e.g., the conductive spiral structure 505-1) that is horizontally disposed, and a second conductive spiral structure (e.g., the conductive spiral structure 505-2) that is horizontally disposed. In some embodiments, the second conductive spiral structure interleaves with the first conductive spiral structure.

Additionally, or alternatively and in embodiments, an integrated assembly (e.g., the semiconductor device 300) includes a device region (e.g., the device region 305). The device region includes a capacitor structure (e.g., the capacitor structure 210)) that includes a first conductive pectinate structure (e.g., the conductive pectinate structure 605-1) that includes a first set of sinusoidal beams (e.g., the beams 610-1) that are horizontally disposed within a metallization layer (e.g., the metallization layer 340) of the device region. The capacitor structure includes a second conductive pectinate structure (e.g., the conductive pectinate structure 605-2) that includes a second set of sinusoidal beams (e.g., the metallization layer 340)) that are horizontally disposed within the metallization layer and interleave with the first set of sinusoidal beams.

In one or more of these ways, the capacitor structure may address the need for improved capacitor architectures by leveraging both 2D layout and 3D structural improvements of NAND semiconductor devices. This results in increased capacitance per unit area and a reduction in parasitic capacitance, which may improve a charge pump efficiency to satisfy performance thresholds of NAND semiconductor devices as the NAND semiconductor devices advance to smaller geometries.

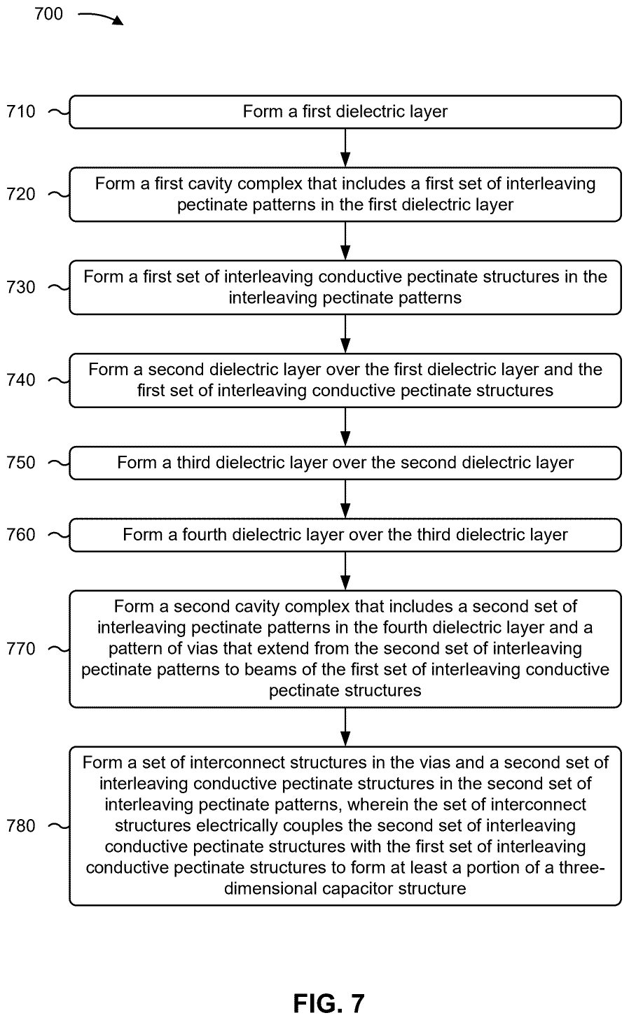

FIG. 7 is a flowchart of an example method 700 of forming an integrated assembly or memory device having a multi-dimension capacitor structure described herein (e.g., the implementation 400 of the capacitor structure 210 as described in connection with FIG. 4A and FIG. 4B). In some embodiments, one or more process blocks of FIG. 7 may be performed by various semiconductor manufacturing equipment.

As shown in FIG. 7, the method 700 may include forming a first dielectric layer (block 710). As further shown in FIG. 7, the method 700 may include forming a first cavity complex that includes a first set of interleaving pectinate patterns in the first dielectric layer (block 720). As further shown in FIG. 7, the method 700 may include forming a first set of interleaving conductive pectinate structures (e.g., the conductive pectinate structures 405-1a and the 405-2a) in the interleaving pectinate patterns (block 730). As further shown in FIG. 7, the method 700 may include forming a second dielectric layer over the first dielectric layer and the first set of interleaving conductive pectinate structures (block 740). As further shown in FIG. 7, the method 700 may include forming a third dielectric layer over the second dielectric layer (block 750). As further shown in FIG. 7, the method 700 may include forming a fourth dielectric layer over the third dielectric layer (block 760). As further shown in FIG. 7, the method 700 may include forming a second cavity complex that includes a second set of interleaving pectinate patterns in the fourth dielectric layer and a pattern of vias that extend from the second set of interleaving pectinate patterns to beams of the first set of interleaving conductive pectinate structures (block 770). As further shown in FIG. 7, the method 700 may include forming a set of interconnect structures (e.g., the interconnect structures 350) in the vias and a second set of interleaving conductive pectinate structures (e.g., the conductive pectinate structures 405-1b and 405-2b) in the second set of interleaving pectinate patterns, wherein the set of interconnect structures electrically couples the second set of interleaving conductive pectinate structures with the first set of interleaving conductive pectinate structures to form at least a portion of a three-dimensional capacitor structure (block 780).

The method 700 may include additional aspects, such as any single aspect or any combination of aspects described below or in connection with one or more other methods described elsewhere herein.

In a first aspect, forming the first set of interleaving conductive pectinate structures includes forming a conductive layer (e.g., the metallization layer 340-1) in the first cavity complex and over the first dielectric layer, and planarizing the conductive layer to expose the first set of interleaving conductive pectinate structures.

In a second aspect, alone or in combination with the first aspect, forming the first cavity complex and the second cavity complex includes forming the first cavity complex and the second cavity complex to have same approximately linear portions (e.g., the approximately linear beams 410-1 or 410-2) having same nominal dimensions.

In a third aspect, alone or in combination with one or more of the first and second aspects, forming the first cavity complex and the second cavity complex includes forming the first cavity complex and the second cavity complex to have same nominal sinusoidal portions (e.g., the sinusoidal beams 610-1 or 610-2) having same nominal dimensions.

In a fourth aspect, alone or in combination with one or more of the first through third aspects, forming the second cavity complex includes aligning the second cavity complex with the first set of interleaving conductive pectinate structures.

Although FIG. 7 shows example blocks of the method 700, in some embodiments, the method 700 may include additional blocks, fewer blocks, different blocks, or differently arranged blocks than those depicted in FIG. 7. In some embodiments, the method 700 may include forming the conductive pectinate structure 405, an integrated assembly that includes the conductive pectinate structure 405, any part described herein of the conductive pectinate structure 405, or any part described herein of an integrated assembly that includes the conductive pectinate structure 405. Additionally, or alternatively, the method 700 may include forming two or more of the metallization layers 340, two or more sets of interleaving pectinate structures 405 that include the approximately linear beams 410 or that include the sinusoidal beams 610, or multiples of interconnect structure 350 joining two or more sets of interleaving pectinate structures 405.

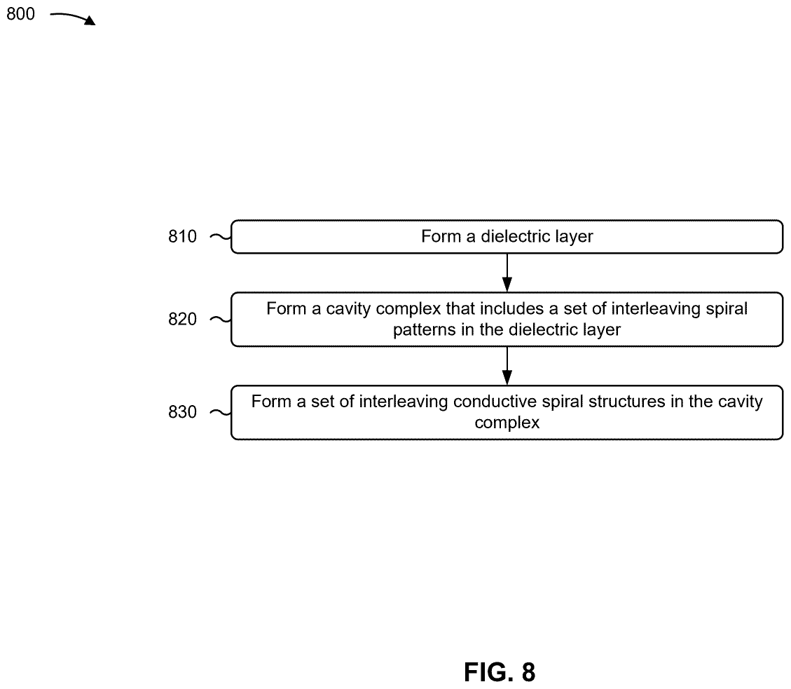

FIG. 8 is a flowchart of an example method 800 of forming an integrated assembly or memory device having a multi-dimension capacitor structure described herein (e.g., the implementation 500 of the capacitor structure 210 as described in connection with FIG. 5A and FIG. 5B). In some embodiments, one or more process blocks of FIG. 8 may be performed by various semiconductor manufacturing equipment.

As shown in FIG. 8, the method 800 may include forming a dielectric layer (block 810). As further shown in FIG. 8, the method 800 may include forming a cavity complex that includes a set of interleaving spiral patterns in the dielectric layer (block 820). As further shown in FIG. 8, the method 800 may include forming a set of interleaving conductive spiral structures (e.g., the conductive spiral structures 505-1a and 505-2a) in the cavity complex (block 830).

The method 800 may include additional aspects, such as any single aspect or any combination of aspects described below or in connection with one or more other methods described elsewhere herein.

In a first aspect, forming the cavity complex that includes the set of interleaving spiral patterns includes forming a set of interleaving square spiral patterns.

In a second aspect, alone or in combination with the first aspect, forming the interleaving conductive spiral structures includes forming a capacitor (e.g., the capacitor structure 210) of a charge pump (e.g., the charge pump circuit 200) for a NAND memory device (e.g., the semiconductor device 300).

In a third aspect, alone or in combination with one or more of the first and second aspects, the dielectric layer is a first dielectric layer, the cavity complex is a first cavity complex, the set of interleaving spiral patterns is a first set of interleaving spiral patterns, and the set of interleaving conductive spiral structures is a first set of interleaving conductive spiral structures, and the method 800 further includes forming a second dielectric layer over the first dielectric layer and the first set of interleaving conductive spiral structures, forming a third dielectric layer over the second dielectric layer, forming a fourth dielectric layer over the third dielectric layer, forming a second cavity complex that includes a second set of interleaving spiral patterns in the fourth dielectric layer and a pattern of vias that extend from the second set of interleaving spiral patterns to segments of the first set of interleaving conductive spiral structures, and forming a set of interconnect structures (e.g., the interconnect structures 350)) in the vias and a second set of interleaving conductive spiral structures (e.g., the conductive spiral structures 505-1b and 505-2b) in the second set of interleaving spiral patterns, wherein the set of interconnect structures electrically couples the second set of interleaving conductive spiral structures with the first set of interleaving conductive spiral structures to form at least a portion of a three-dimensional capacitor structure.

In a fourth aspect, alone or in combination with one or more of the first through third aspects, forming the first set of interleaving conductive spiral structures includes forming a conductive layer (e.g., the metallization layer 340-1) in the first cavity complex and over the first dielectric layer, and planarizing the conductive layer to expose the first set of interleaving conductive spiral structures.

In a fifth aspect, alone or in combination with one or more of the first through fourth aspects, forming the first cavity complex and the second cavity complex includes forming the first cavity complex and the second cavity complex to include square spiral portions having same nominal dimensions.

Although FIG. 8 shows example blocks of the method 800, in some embodiments, the method 800 may include additional blocks, fewer blocks, different blocks, or differently arranged blocks than those depicted in FIG. 8. In some embodiments, the method 800 may include forming the conductive spiral structure 505, an integrated assembly that includes the conductive spiral structure 505, any part described herein of the conductive spiral structure 505, or any part described herein of an integrated assembly that includes the conductive spiral structure 505. Additionally, or alternatively, the method 800 may include forming two or more of the metallization layers 340, two or more of the conductive spiral structures 505, and two or more of the interconnect structure 350).

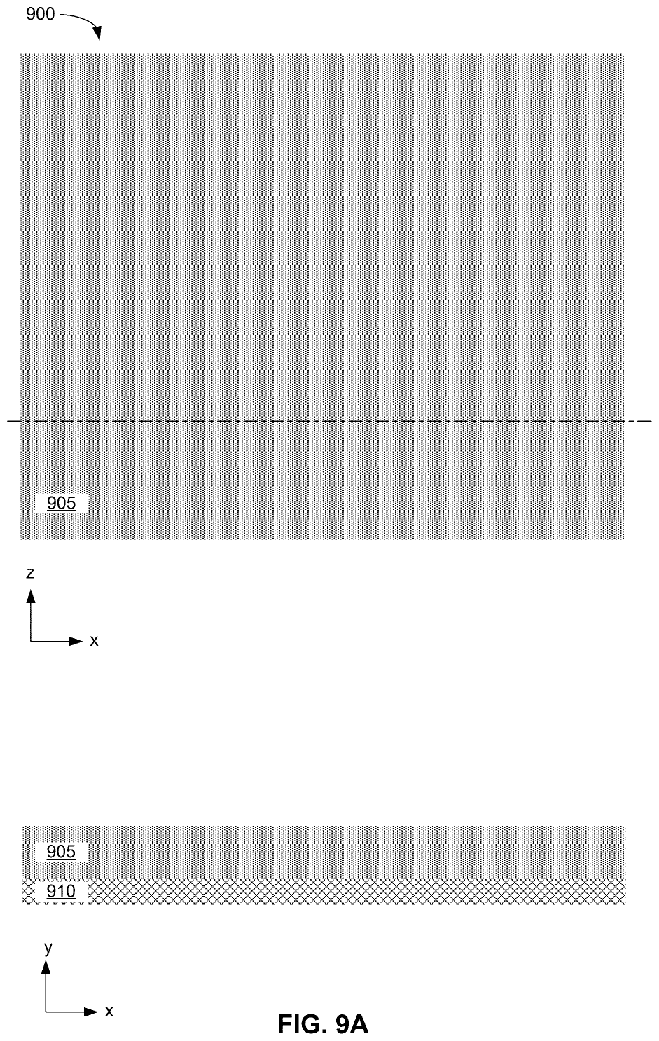

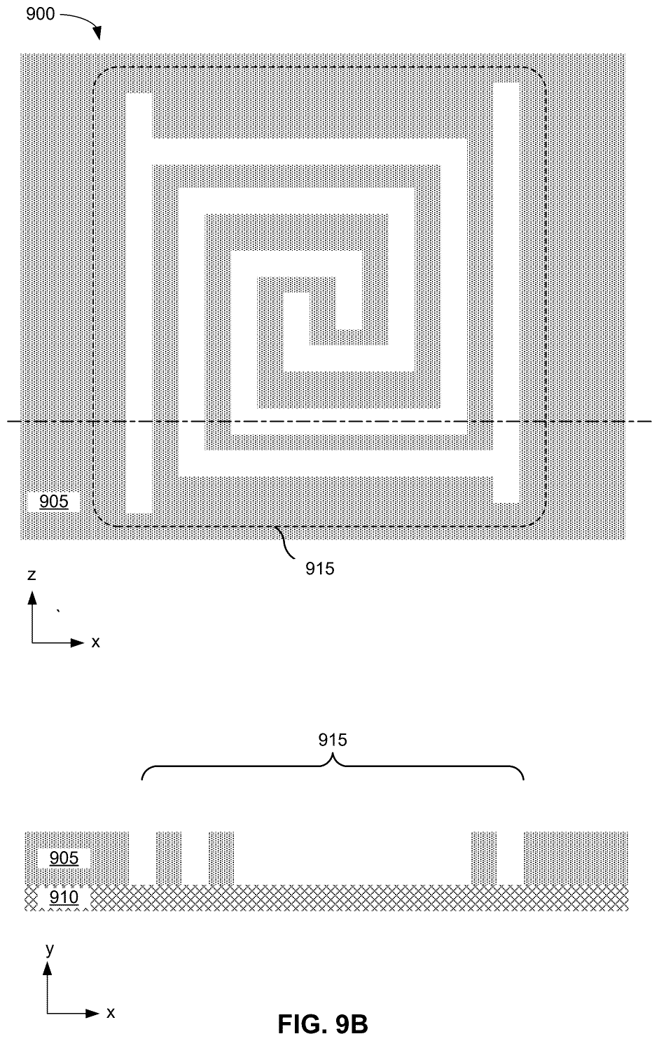

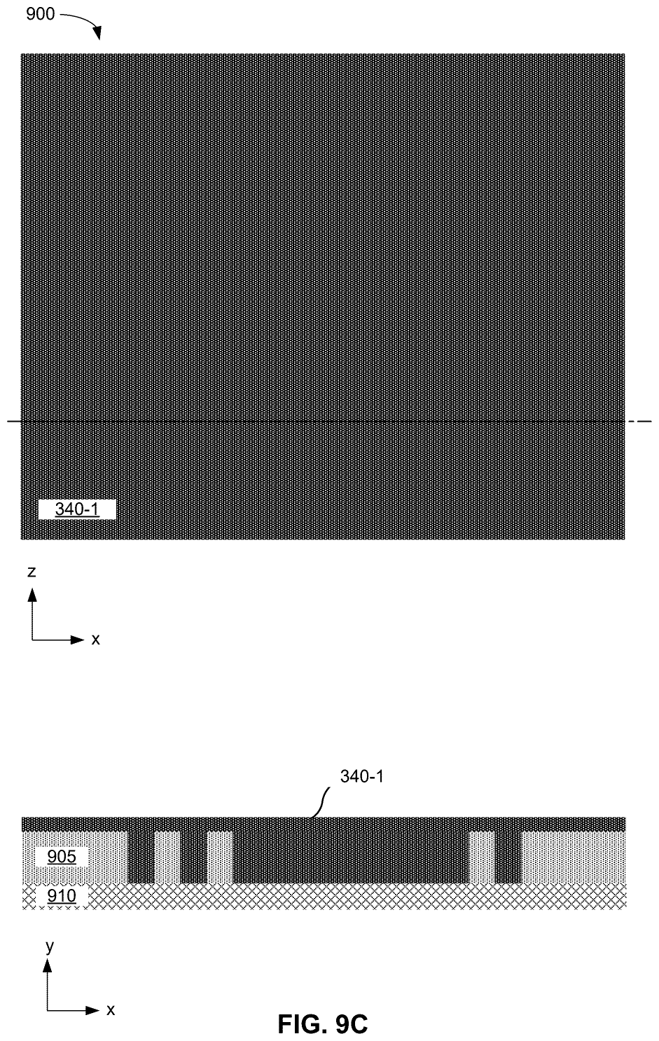

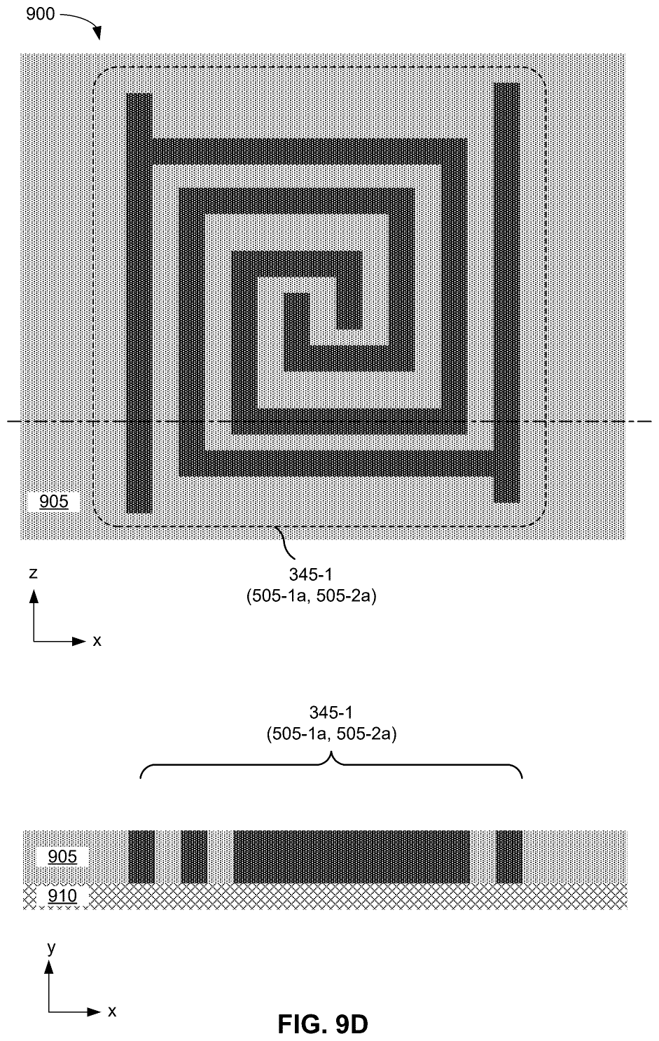

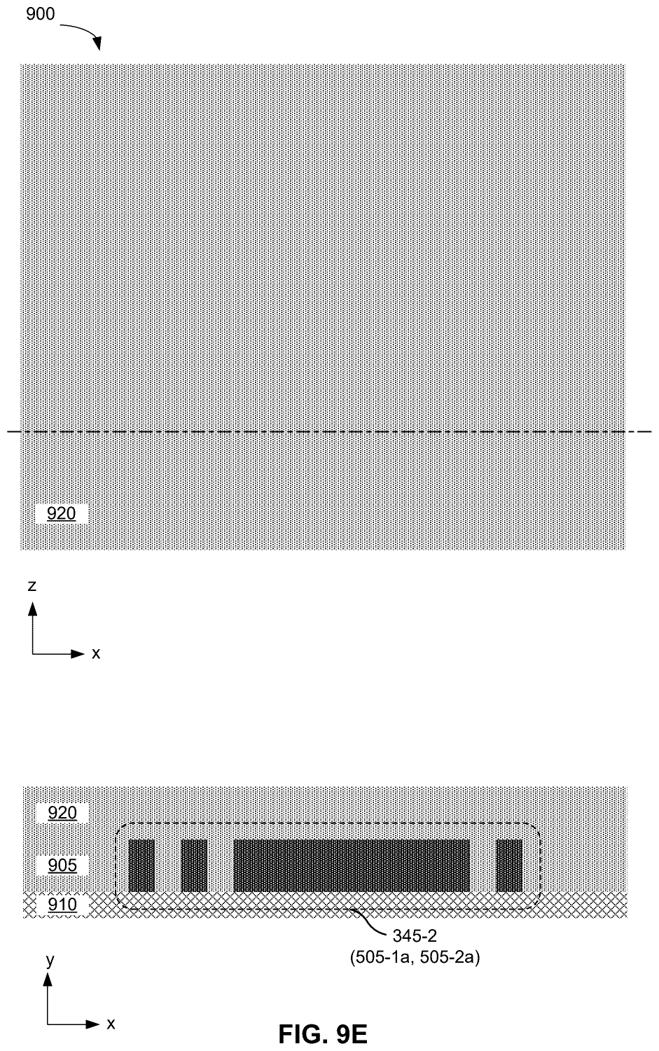

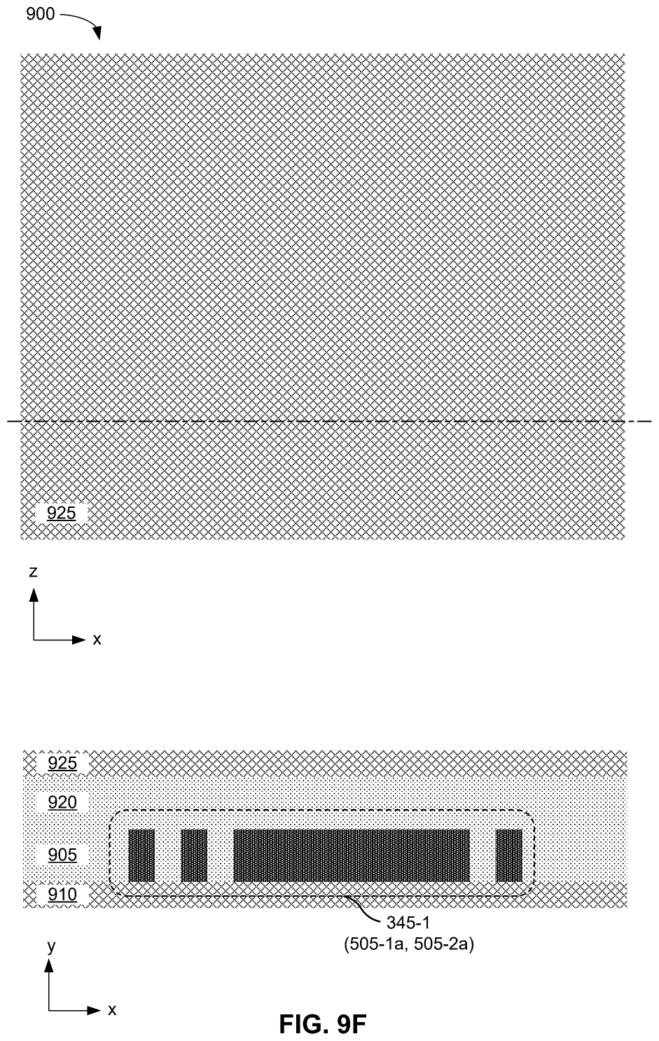

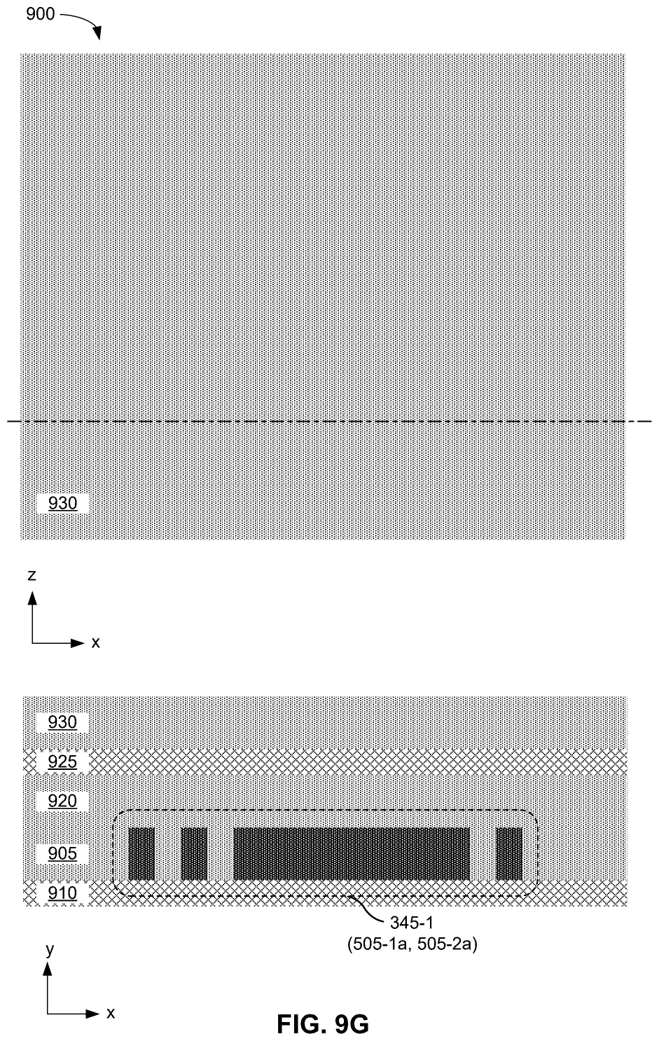

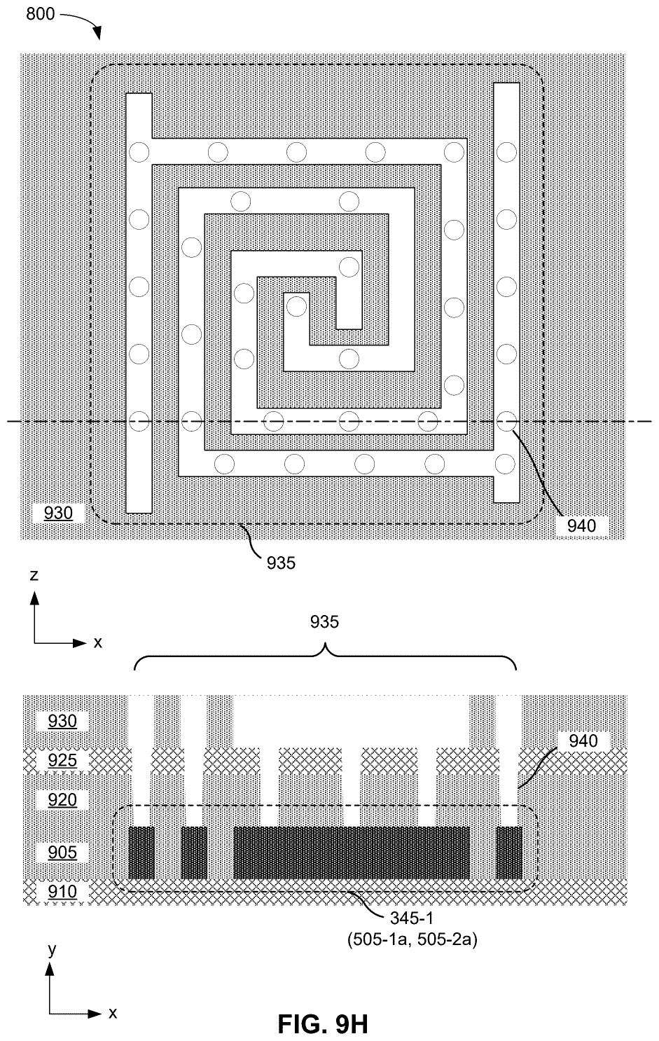

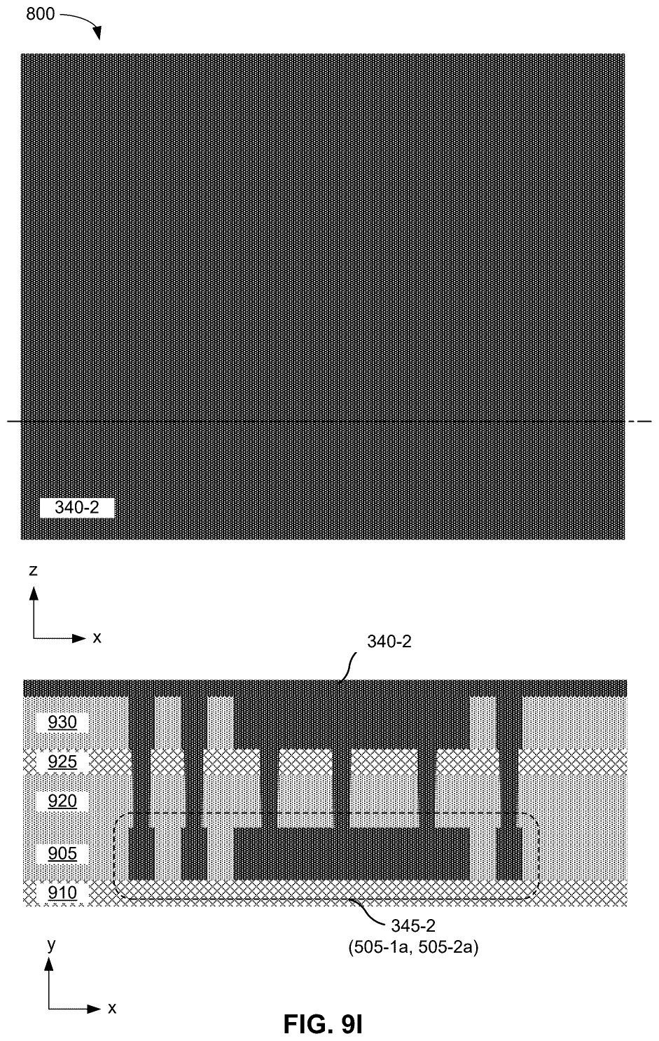

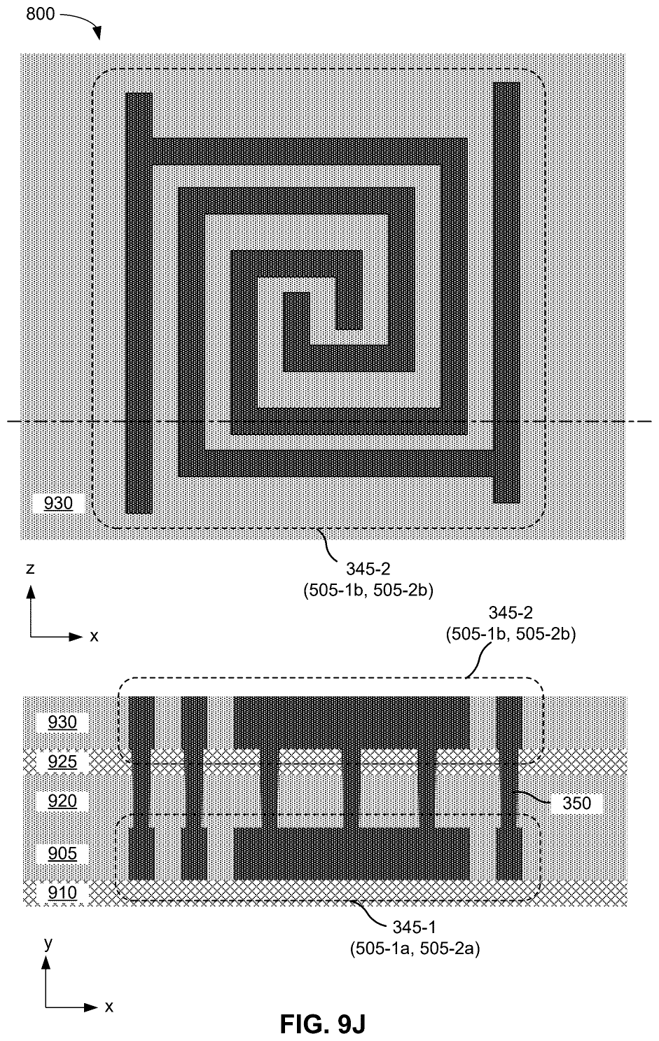

FIGS. 9A through 9J are diagrammatic views showing formation of the capacitor structure 210 at example process stages of an example process 900 of forming the capacitor structure 210. In some embodiments, the process 900 described below in connection with FIGS. 9A through 9J may correspond to the method 800 or one or more blocks of the method 800 (e.g., the implementation 500 using the conductive spiral structures 505). Additionally, or alternatively and in some embodiments, the process 900 described below in connection with FIGS. 9A through 9J may correspond to the method 700 or one or more blocks of the method 700 (e.g., the implementation 400 using the conductive pectinate structures 405). However, the process 900 described below is an example, and other example processes may be used to form the capacitor structure 210, an integrated assembly that includes the capacitor structure 210, or one or more parts of the capacitor structure 210 or the integrated assembly.

As shown in FIG. 9A, the process 900 may include forming (e.g., depositing or growing) a dielectric layer 910 over or on a dielectric layer 905. The dielectric layer 905 may comprise, consist of, or consist essentially of nitride, among other examples. The dielectric layer 910 may comprise, consist of, or consist essentially of silicon dioxide, among other examples.

As shown in FIGS. 9B, the process may include removing (e.g., etching) a portion of the dielectric layer 905 to form a cavity complex 915 that includes a set of interleaving spiral patterns. In some embodiments, and as shown in FIG. 9B, the set of interleaving spiral patterns includes square spiral patterns. However, other shapes of interleaving spiral patterns are within the scope of the present disclosure (curved, rectangular, or triangular shapes, among examples).

The removal may remove the dielectric layer 905 down to the dielectric layer 910. In some embodiments, one or more masks may be used to form the cavity complex 915. For example, one or more masks may be deposited or patterned on the dielectric layer 905 to remove material to form the cavity complex 915.

As shown in FIG. 9C, the process 900 may include forming (e.g., depositing or growing) the metallization layer 340-1 in the cavity complex 915 and over or on the dielectric layer 905. The metallization layer 340-1 may comprise, consist of, or consist essentially of a metal (e.g., titanium, tungsten, cobalt, nickel, platinum, or ruthenium), a metal composition (e.g., a metal silicide, a metal carbine, or a metal nitride, such as titanium nitride or titanium silicon nitride), or a conductively-doped semiconductor material (e.g., conductively-doped silicon, conductively-doped germanium, or conductively-doped gallium arsenide), among other examples.

As shown in FIG. 9D, the process may include planarizing the metallization layer 340-1 to expose a set of interleaving conductive spiral structures (e.g., the set of interleaving conductive spiral structures 345-1). For example, the metallization layer 340-1 may be planarized using chemical-mechanical polishing or another suitable planarization technique.

As shown in FIG. 9E, the process 900 may include forming (e.g., depositing or growing) a dielectric layer 920 over or on the dielectric layer 905. The dielectric layer 920 may comprise, consist of, or consist essentially of silicon dioxide, among other examples.

As shown in FIG. 9F, the process 900 may include forming (e.g., depositing or growing) a dielectric layer 925 over or on the dielectric layer 920. The dielectric layer 925 may comprise, consist of, or consist essentially of nitride, among other examples.

As shown in FIG. 9G, the process 900 may include forming (e.g., depositing or growing) a dielectric layer 930 over or on the dielectric layer 925. The dielectric layer 925 may comprise, consist of, or consist essentially of silicon dioxide, among other examples.

As shown in FIG. 9H, the process 900 may include removing (e.g., etching) portions of the dielectric layer 930, the dielectric layer 925, or the dielectric layer 920 to form a cavity complex 935 that includes a set of interleaving spiral patterns. In some embodiments, the interleaving spiral patterns of the cavity complex 935 have dimensions, geometries, or segments that are substantially similar to those of the interleaving spiral patterns of the cavity complex 915 described in connection with FIG. 9B. Additionally, or alternatively, the interleaving spiral patterns of the cavity complex 935 may vertically align with (e.g., be directly above or at least partially overlap with) the set of interleaving conductive spiral structures 345-1. Further, and as shown in FIG. 9H, the cavity complex 935 may include a pattern of vias 940 (e.g., vertical interconnect access holes) that extend to segments of the interleaving conductive spiral structures 345-1.

In some embodiments, two or more masks may be used to form the cavity complex 935. For example, a first mask may be deposited or patterned on the dielectric layer 930 to remove material from the dielectric layer 930, the dielectric layer 925, and the dielectric layer 920 to form the pattern of vias 940. Additionally, or alternatively, a second mask may be deposited or patterned on the dielectric layer 930 to remove material to form the set of interleaving spiral patterns.

As shown in FIG. 91, the process 900 may include forming (e.g., depositing or growing) the metallization layer 340-2 in the cavity complex 935 and over or on the dielectric layer 930. The metallization layer 340-2 may comprise, consist of, or consist essentially of a metal (e.g., titanium, tungsten, cobalt, nickel, platinum, or ruthenium), a metal composition (e.g., a metal silicide, a metal carbine, or a metal nitride, such as titanium nitride or titanium silicon nitride), or a conductively-doped semiconductor material (e.g., conductively-doped silicon, conductively-doped germanium, or conductively-doped gallium arsenide), among other examples.

As shown in FIG. 9J, the process may include planarizing the metallization layer 340-2 to expose the set of interleaving conductive spiral structures 345-2. For example, the metallization layer 340-2 may be planarized using chemical-mechanical polishing or another suitable planarization technique. Further, and as shown in FIG. 9J, the interconnect structures 350 extend from the set of interleaving conductive spiral structures 345-2 to the set of interleaving conductive spiral structures 345-1.

One or more operations described in connection with FIG. 9A through FIG. 9J may be repeated to form additional dielectric layers or sets of conductive spiral structures to form a capacitor structure (e.g., the capacitor structure 210) having a desired performance characteristic. Additionally, or alternatively, patterns described in connection with FIG. 9A through FIG. 9J may be altered or replaced to form other structures or beams describe herein (the conductive pectinate structures 405 including the approximately linear beams 410 or the sinusoidal beams 610, among other examples).

As indicated above, the process steps described in connection with FIGS. 9A through 9J are provided as examples. Other examples may differ from what is described with respect to FIGS. 9A through 9J. The structure shown in FIGS. 9J may be equivalent to a portion of the implementation 400 of the capacitor structure 210 described elsewhere herein. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

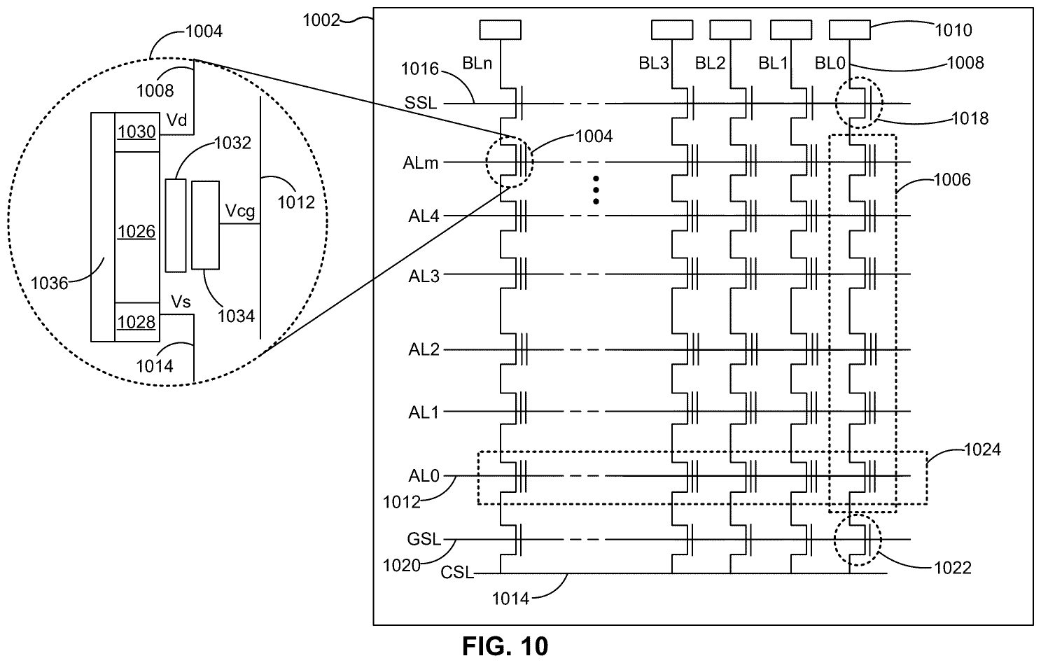

FIG. 10 is a diagram of example components included in a memory array 1002. In FIG. 10, the memory array 1002 is a NAND memory array. However, in some embodiments, the memory array 1002 may be another type of memory array, such as a NOR memory array, a resistive RAM (RRAM) memory array, a magnetoresistive RAM (MRAM) memory array, a ferroelectric RAM (FeRAM) memory array, a spin-transfer torque RAM (STT-RAM) memory array, or the like. In some embodiments, the memory array 1002 is part of a three-dimensional stack of memory arrays, such as 3D NAND flash memory, 3D NOR flash memory, or the like.

The memory array 1002 includes multiple memory cells 1004. A memory cell 1004 may store an analog value, such as an electrical voltage or an electrical charge, that represents a data state (e.g., a digital value). The analog value and corresponding data state depend on a quantity of electrons trapped or present within a region of the memory cell 1004 (e.g., in a charge trap, such as a floating gate), as described below.

A NAND string 1006 (sometimes called a string) may include multiple memory cells 1004 connected in series. A NAND string 1006 is coupled to a bit line 1008 (sometimes called a digit line or a column line, and shown as BL0-BLn). Data can be read from or written to the memory cells 1004 of a NAND string 1006 via a corresponding bit line 1008 using one or more input/output (I/O) components 1010 (e.g., an I/O circuit, an I/O bus, a page buffer, or a sensing component, such as a sense amplifier). Memory cells 1004 of different NAND strings 1006 (e.g., one memory cell 1004 per NAND string 1006) may be coupled with one another via access lines 1012 (sometimes called word lines or row lines, and shown as AL0-ALm) that select which row (or rows) of memory cells 1004 is affected by a memory operation (e.g., a read operation or a write operation).

A NAND string 1006 may be connected to a bit line 1008 at one end and a common source line (CSL) 1014 at the other end. A string select line (SSL) 1016 may be used to control respective string select transistors 1018. A string select transistor 1018 selectively couples a NAND string 1006 to a corresponding bit line 1008. A ground select line (GSL) 1020 may be used to control respective ground select transistors 1022. A ground select transistor 1022 selectively couples a NAND string 1006 to the common source line 1014.

A “page” of memory (or “a memory page”) may refer to a group of memory cells 1004 connected to the same access line 1012, as shown by reference number 1024. In some embodiments (e.g., for single-level cells), the memory cells 1004 connected to an access line 1012 may be associated with a single page of memory. In some embodiments (e.g., for multi-level cells), the memory cells 1004 connected to an access line 1012 may be associated with multiple pages of memory, where each page represents one bit stored in each of the memory cells 1004 (e.g., a lower page that represents a first bit stored in each memory cell 1004 and an upper page that represents a second bit stored in each memory cell 1004). In NAND memory, a page is the smallest physically addressable data unit for a write operation (sometimes called a program operation).

In some embodiments, a memory cell 1004 is a floating-gate transistor memory cell. In this case, the memory cell 1004 may include a channel 1026, a source region 1028, a drain region 1030, a floating gate 1032, and a control gate 1034. The source region 1028, the drain region 1030, and the channel 1026 may be on a substrate 1036 (e.g., a semiconductor substrate). A memory device may store a data state in the memory cell 1004 by charging the floating gate 1032 to a particular voltage associated with the data state or to a voltage that is within a range of voltages associated with the data state. This results in a predefined amount of current flowing through the channel 1026 (e.g., from the source region 1028 to the drain region 1030) when a specified read voltage is applied to the control gate 1034 (e.g., by a corresponding access line 1012 connected to the control gate 1034). Although not shown, a tunnel oxide layer (or tunnel dielectric layer) may be interposed between the floating gate 1032 and the channel 1026, and a gate oxide layer (e.g., a gate dielectric layer) may be interposed between the floating gate 1032 and the control gate 1034. As shown, a drain voltage Vd may be supplied from a bit line 1008, a control gate voltage Veg may be supplied from an access line 1012, and a source voltage Vs may be supplied via the common source line 1014 (which, in some embodiments, is a ground voltage).

To write or program the memory cell 1004, Fowler-Nordheim tunneling may be used. For example, a strong positive voltage potential may be created between the control gate 1034 and the channel 1026 (e.g., by applying a large positive voltage to the control gate 1034 via a corresponding access line 1012) while current is flowing through the channel 1026 (e.g., from the common source line 1014 to the bit line 1008, or vice versa). The strong positive voltage at the control gate 1034 causes electrons within the channel 1026 to tunnel through the tunnel oxide layer and be trapped in the floating gate 1032. These negatively charged electrons then act as an electron barrier between the control gate 1034 and the channel 1026 that increases the threshold voltage of the memory cell 1004. The threshold voltage is a voltage required at the control gate 1034 to cause current (e.g., a threshold amount of current) to flow through the channel 1026. Fowler-Nordheim tunneling is an example technique for storing a charge in the floating gate, and other techniques, such as channel hot electron injection, may be used.

To read the memory cell 1004, a read voltage may be applied to the control gate 1034 (e.g., via a corresponding access line 1012), and an I/O component 1010 (e.g., a sense amplifier) may determine the data state of the memory cell 1004 based on whether current passes through the memory cell 1004 (e.g., the channel 1026) due to the applied voltage. A pass voltage may be applied to all memory cells 1004 (other than the memory cell 1004 being read) in the same NAND string 1006 as the memory cell 1004 being read. For example, the pass voltage may be applied on each access line 1012 other than the access line 1012 of the memory cell 1004 being read (e.g., where the read voltage is applied). The pass voltage is higher than the highest read voltage associated with any memory cell data states so that all of the other memory cells 1004 in the NAND string 1006 conduct, and the I/O component 1010 can detect a data state of the memory cell 1004 being read by sensing current (or lack thereof) on a corresponding bit line 1008. For example, in a single-level memory cell that stores one of two data states, the data state is a “1” if current is detected, and the data state is a “0” if current is not detected. In a multi-level memory cell that stores one of three or more data states, multiple read voltages are applied, over time, to the control gate 1034 to distinguish between the three or more data states and determine a data state of the memory cell 1004.

To erase the memory cell 1004, a strong negative voltage potential may be created between the control gate 1034 and the channel 1026 (e.g., by applying a large negative voltage to the control gate 1034 via a corresponding access line 1012). The strong negative voltage at the control gate 1034 causes trapped electrons in the floating gate 1032 to tunnel back across the oxide layer from the floating gate 1032 to the channel 1026 and to flow between the common source line 1014 and the bit line 1008. This removes the electron barrier between the control gate 1034 and the channel 1026 and decreases the threshold voltage of the memory cell 1004 (e.g., to an empty or erased state, which may represent a “1”). In NAND memory, a block is the smallest unit of memory that can be erased. A block of NAND memory includes multiple pages. Thus, an individual page of a block cannot be erased without erasing every other page of the block. In some embodiments, a block may be divided into multiple sub-blocks. A sub-block is a portion of a block and may include a subset of pages of the block or a subset of memory cells of the block.

In some embodiments, one or more of the memory cells 1004 may be electrically coupled with a charge pump circuit (e.g., the charge pump circuit 200 of FIG. 2). The charge pump circuit may include one or more embodiments of a capacitor structure described herein (e.g., the implementation 400 of the capacitor structure 210, the implementation 500 of the capacitor structure 210, or the implementation 600 of the capacitor structure 210).

As indicated above, FIG. 10 is provided as an example. Other examples may differ from what is described with regard to FIG. 10.

In some embodiments, an integrated assembly includes a device region, comprising: a capacitor structure, comprising: a first conductive pectinate structure that is horizontally disposed and interleaves with a second conductive pectinate structure that is horizontally disposed, wherein first beams of the first conductive pectinate structure and second beams of the second conductive pectinate structure are spaced on a same nominal pitch, and wherein the first beams and the second beams have a same nominal length: and a third conductive pectinate structure that is horizontally disposed interleaving with a fourth conductive pectinate structure that is horizontally disposed, wherein third beams of the third conductive pectinate structure and fourth beams of the fourth conductive pectinate structure are spaced on the same nominal pitch as the first beams and the second beams, wherein the third beams and the fourth beams have the same nominal length as the first beams and the second beams, wherein the third beams are vertically aligned with the first beams, and wherein the fourth beams are vertically aligned with the second beams.

In some embodiments, an integrated assembly includes a device region, comprising: a capacitor structure, comprising: a first conductive spiral structure that is horizontally disposed: and a second conductive spiral structure that is horizontally disposed, wherein the second conductive spiral structure interleaves with the first conductive spiral structure.

In some embodiments, an integrated assembly includes a device region, comprising: a capacitor structure, comprising: a first conductive pectinate structure comprising: a first set of sinusoidal beams that are horizontally disposed within a metallization layer of the device region: and a second conductive pectinate structure, comprising: a second set of sinusoidal beams that are horizontally disposed within the metallization layer and interleave with the first set of sinusoidal beams.

In some embodiments, a method includes forming a first dielectric layer: forming a first cavity complex that includes a first set of interleaving pectinate patterns in the first dielectric layer: forming a first set of interleaving conductive pectinate structures in the interleaving pectinate patterns: forming a second dielectric layer over the first dielectric layer and the first set of interleaving conductive pectinate structures: forming a third dielectric layer over the second dielectric layer: forming a fourth dielectric layer over the third dielectric layer: forming a second cavity complex that includes a second set of interleaving pectinate patterns in the fourth dielectric layer and a pattern of vias that extend from the second set of interleaving pectinate patterns to beams of the first set of interleaving conductive pectinate structures: and forming a set of interconnect structures in the vias and a second set of interleaving conductive pectinate structures in the second set of interleaving pectinate patterns, wherein the set of interconnect structures electrically couples the second set of interleaving conductive pectinate structures with the first set of interleaving conductive pectinate structures to form at least a portion of a three-dimensional capacitor structure.

In some embodiments, a method includes forming a dielectric layer: forming a cavity complex that includes a set of interleaving spiral patterns in the dielectric layer: and forming a set of interleaving conductive spiral structures in the cavity complex.

The foregoing disclosure provides illustration and description but is not intended to be exhaustive or to limit the embodiments to the precise forms disclosed. Modifications and variations may be made in light of the above disclosure or may be acquired from practice of the embodiments described herein.

The orientations of the various elements in the figures are shown as examples, and the illustrated examples may be rotated relative to the depicted orientations. The descriptions provided herein, and the claims that follow; pertain to any structures that have the described relationships between various features, regardless of whether the structures are in the particular orientation of the drawings, or are rotated relative to such orientation. Similarly, spatially relative terms, such as “below,” “beneath.” “lower,” “above.” “upper,” “middle.” “left.” and “right,” are used herein for ease of description to describe one element's relationship to one or more other elements as illustrated in the figures. The spatially relative terms are intended to encompass different orientations of the element, structure, or assembly in use or operation in addition to the orientations depicted in the figures. A structure or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims or disclosed in the specification, these combinations are not intended to limit the disclosure of embodiments described herein. Many of these features may be combined in ways not specifically recited in the claims or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “or,” unless explicitly stated otherwise (e.g., if used in combination with “either” or “only one of”).

1. An integrated assembly, comprising:
a device region, comprising:
a capacitor structure, comprising:
a first conductive pectinate structure that is horizontally disposed and interleaves with a second conductive pectinate structure that is horizontally disposed,
wherein first beams of the first conductive pectinate structure and second beams of the second conductive pectinate structure are spaced on a same nominal pitch, and
wherein the first beams and the second beams have a same nominal length; and
a third conductive pectinate structure that is horizontally disposed interleaving with a fourth conductive pectinate structure that is horizontally disposed,
wherein third beams of the third conductive pectinate structure and fourth beams of the fourth conductive pectinate structure are spaced on the same nominal pitch as the first beams and the second beams,
wherein the third beams and the fourth beams have the same nominal length as the first beams and the second beams,
wherein the third beams are vertically aligned with the first beams, and
wherein the fourth beams are vertically aligned with the second beams.

2. The integrated assembly of claim 1, wherein the capacitor structure further comprises:
an interconnect structure that is vertically oriented and that electrically couples one of the first beams and one of the third beams.

3. The integrated assembly of claim 2 wherein the first beams and the third beams have a same nominal thickness, and
wherein the interconnect structure has:
a nominal width that is less than or equal to the same nominal thickness.

4. The integrated assembly of claim 2 wherein the first beams and the third beams have a same nominal thickness, and
wherein the interconnect structure have:
a nominal width that is greater than the same nominal thickness.

5. The integrated assembly of claim 4, wherein the interconnect structure is a first interconnect structure, and
wherein the capacitor structure further comprises:
a second interconnect structure that electrically couples one of the second beams with one of the fourth beams.

6. The integrated assembly of claim 5, wherein the same nominal thickness is a first same nominal thickness, the nominal width is a first nominal width, and
wherein the second beams and the fourth beams have:
a second same nominal thickness, and
wherein the second interconnect structure has:
a second nominal width that is less than or equal to the second same nominal thickness.

7. The integrated assembly of claim 5, wherein the same nominal thickness is a first same nominal thickness, the nominal width is a first nominal width, and
wherein the second beams and the fourth beams have:
a second same nominal thickness, and
wherein the second interconnect structure has:
a second nominal width that is greater than the second same nominal thickness.

8. The integrated assembly of claim 1, wherein the first conductive pectinate structure and the second conductive pectinate structure are part of a first metallization layer of the device region, and
wherein the third conductive pectinate structure and the fourth conductive pectinate structure are part of a second metallization layer of the device region.

9. The integrated assembly of claim 8, further comprising:
a fifth conductive pectinate structure and a sixth conductive pectinate structure that are part of a third metallization layer of the device region,
wherein the fifth conductive pectinate structure is electrically coupled with the third conductive pectinate structure and the sixth conductive pectinate structure is electrically coupled with the fourth conductive pectinate structure.

10. The integrated assembly of claim 1, wherein one or more of the first beams, the second beams, the third beams, or the fourth beams comprise:
approximately linear beams.

11. The integrated assembly of claim 1, wherein one or more of the first beams, the second beams, the third beams, or the fourth beams comprise:
sinusoidal beams.

12. An integrated assembly, comprising:
a device region, comprising:
a capacitor structure, comprising:
a first conductive spiral structure that is horizontally disposed; and
a second conductive spiral structure that is horizontally disposed,
wherein the second conductive spiral structure interleaves with the first conductive spiral structure.

13. The integrated assembly of claim 12, wherein the first conductive spiral structure and the second conductive spiral structure are part of a metallization layer in the device region.

14. The integrated assembly of claim 13, wherein the metallization layer is a first metallization layer, and wherein the capacitor structure further comprises:
a third conductive spiral structure that is horizontally disposed,
wherein the third conductive spiral structure is part of a second metallization layer of the device region, and
wherein the third conductive spiral structure is vertically aligned with the first conductive spiral structure; and
a fourth conductive spiral structure that is horizontally disposed,
wherein the fourth conductive spiral structure is part of the second metallization layer,
wherein the fourth conductive spiral structure is vertically aligned with the second conductive spiral structure, and
wherein the fourth conductive spiral structure interleaves with the third conductive spiral structure.

15. The integrated assembly of claim 14, wherein at least one of the first conductive spiral structure, the second conductive spiral structure, the third conductive spiral structure, or the fourth conductive spiral structure comprises:
a square-shaped conductive spiral structure.

16. The integrated assembly of claim 14, wherein the capacitor structure further comprises:
an interconnect structure that is vertically oriented and that electrically couples a segment of the first conductive spiral structure with a segment of the third conductive spiral structure.

17. The integrated assembly of claim 16, wherein the segment of the first conductive spiral structure and the segment of the third conductive spiral structure have a same nominal thickness, and
wherein the interconnect structure has:
a nominal width that is less than or equal to the same nominal thickness.

18. The integrated assembly of claim 16, wherein the segment of the first conductive spiral structure and the segment of the third conductive spiral structure have a same nominal thickness, and
wherein the interconnect structure has:
a nominal width that is greater than the same nominal thickness.

19. The integrated assembly of claim 16, wherein the interconnect structure is a first interconnect structure, and
wherein the capacitor structure further comprises:
a second interconnect structure that electrically couples a segment of the second conductive spiral structure with a segment of the fourth conductive spiral structure.

20. The integrated assembly of claim 19, wherein the segment of the second conductive spiral structure and the segment of the fourth conductive spiral structure have a same nominal thickness, and
wherein the second interconnect structure has:
a nominal width that is less than or equal to the same nominal thickness.

21. The integrated assembly of claim 19, wherein the segment of the second conductive spiral structure and the segment of the fourth conductive spiral structure have a same nominal thickness, and
wherein the second interconnect structure has:
a nominal width that is greater than the same nominal thickness.

22. The integrated assembly of claim 12, wherein the capacitor structure is part of a charge pump circuit for a NAND memory device.

23. An integrated assembly, comprising:
a device region, comprising:
a capacitor structure, comprising:
a first conductive pectinate structure comprising:
a first set of sinusoidal beams that are horizontally disposed within a metallization layer of the device region; and
a second conductive pectinate structure, comprising:
a second set of sinusoidal beams that are horizontally disposed within the metallization layer and interleave with the first set of sinusoidal beams.

24. The integrated assembly of claim 23, wherein the first set of sinusoidal beams are of a first polarity, and
wherein the second set of sinusoidal beams are of a second, opposite polarity.

25. A method, comprising:
forming a first dielectric layer;
forming a first cavity complex that includes a first set of interleaving pectinate patterns in the first dielectric layer;
forming a first set of interleaving conductive pectinate structures in the interleaving pectinate patterns;
forming a second dielectric layer over the first dielectric layer and the first set of interleaving conductive pectinate structures;
forming a third dielectric layer over the second dielectric layer;
forming a fourth dielectric layer over the third dielectric layer;
forming a second cavity complex that includes a second set of interleaving pectinate patterns in the fourth dielectric layer and a pattern of vias that extend from the second set of interleaving pectinate patterns to beams of the first set of interleaving conductive pectinate structures; and
forming a set of interconnect structures in the vias and a second set of interleaving conductive pectinate structures in the second set of interleaving pectinate patterns, wherein the set of interconnect structures electrically couples the second set of interleaving conductive pectinate structures with the first set of interleaving conductive pectinate structures to form at least a portion of a three-dimensional capacitor structure.

26. The method of claim 25, wherein forming the first set of interleaving conductive pectinate structures includes:
forming a conductive layer in the first cavity complex and over the first dielectric layer; and
planarizing the conductive layer to expose the first set of interleaving conductive pectinate structures.

27. The method of claim 25, wherein forming the first cavity complex and the second cavity complex includes:
forming the first cavity complex and the second cavity complex to have same approximately linear portions having same nominal dimensions.

28. The method of claim 25, wherein forming the first cavity complex and the second cavity complex includes:
forming the first cavity complex and the second cavity complex to have same nominal sinusoidal portions having same nominal dimensions.

29. The method of claim 25, wherein forming the second cavity complex includes:
aligning the second cavity complex with the first set of interleaving conductive pectinate structures.

30. A method, comprising:
forming a dielectric layer;
forming a cavity complex that includes a set of interleaving spiral patterns in the dielectric layer; and
forming a set of interleaving conductive spiral structures in the cavity complex.

31. The method of claim 30, wherein forming the cavity complex that includes the set of interleaving spiral patterns includes:
forming a set of interleaving square spiral patterns.

32. The method of claim 30, wherein forming the interleaving conductive spiral structures includes:
forming a capacitor of a charge pump for a NAND memory device.

33. The method of claim 30, wherein the dielectric layer is a first dielectric layer, the cavity complex is a first cavity complex, the set of interleaving spiral patterns is a first set of interleaving spiral patterns, and the set of interleaving conductive spiral structures is a first set of interleaving conductive spiral structures, and further including:
forming a second dielectric layer over the first dielectric layer and the first set of interleaving conductive spiral structures;
forming a third dielectric layer over the second dielectric layer;
forming a fourth dielectric layer over the third dielectric layer;
forming a second cavity complex that includes a second set of interleaving spiral patterns in the fourth dielectric layer and a pattern of vias that extend from the second set of interleaving spiral patterns to segments of the first set of interleaving conductive spiral structures; and
forming a set of interconnect structures in the vias and a second set of interleaving conductive spiral structures in the second set of interleaving spiral patterns, wherein the set of interconnect structures electrically couples the second set of interleaving conductive spiral structures with the first set of interleaving conductive spiral structures to form at least a portion of a three-dimensional capacitor structure.

34. The method of claim 33, wherein forming the first set of interleaving conductive spiral structures includes:
forming a conductive layer in the first cavity complex and over the first dielectric layer; and
planarizing the conductive layer to expose the first set of interleaving conductive spiral structures.

35. The method of claim 33, wherein forming the first cavity complex and the second cavity complex includes:
forming the first cavity complex and the second cavity complex to include square spiral portions having same nominal dimensions.
